(19) United States
(12) Patent Application Publication
(10) Pub. No.: US 2026/0007026 A1
(43) Pub. Date: Jan. 1, 2026

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventor: Xuan Li, Beijing (CN)

(21) Appl. No.: 18/706,146

(22) PCT Filed: May 24, 2023
(86) PCT No.: PCT/CN2023/096042

§ 371 Date: Apr. 30, 2024

(51) Int. Cl. H10K 59/35; H10K 59/122; H10K 59/80

(52) U.S. Cl. CPC H10K 59/352; H10K 59/122; H10K 59/353; H10K 59/879; H10K 59/8791

(57) ABSTRACT

A display panel includes a display region and a non-display region. The display panel includes a base substrate and a light-emitting unit. The light-emitting unit is located on a side of the base substrate. The light-emitting unit includes a plurality of light-emitting devices. The plurality of light-emitting devices include a plurality of red light-emitting devices, a plurality of green light-emitting devices and a plurality of blue light-emitting devices. A ratio of a sum of light exit areas of the plurality of blue light-emitting devices to an area of the display region of the display panel is greater than or equal to 4% and less than or equal to 25%.

### CROSS-REFERENCE TO RELATED APPLICATION

This application is the United States national phase entry of International Patent Application No. PCT/CN2023/096042, filed May 24, 2023, the disclosure of which is hereby incorporated by reference in its entirety.

### BACKGROUND OF THE INVENTION

### Field of the Invention

The present disclosure relates to the field of display technologies, and in particular, to a display panel and a display apparatus including the display panel.

### Description of Related Art

Organic light-emitting diodes (OLEDs) are currently the mainstream display products used in intelligent display terminals due to the many advantages such as self-illumination, high luminance, high contrast, high color gamut, fast response, wide viewing angle, low power consumption and flexible display.

In the OLED display products, red light-emitting devices, green light-emitting devices and blue light-emitting devices emit light to achieve full-color display for the OLED display products. At present, the luminous efficiency of red light-emitting devices and the luminous efficiency of green light-emitting devices are both higher than that of blue light-emitting devices.

### SUMMARY OF THE INVENTION

In an aspect, a display panel is provided. The display panel includes a display region and a non-display region. The display panel includes a base substrate and a light-emitting unit. The light-emitting unit is located on a side of the base substrate. The light-emitting unit includes a plurality of light-emitting devices. The plurality of light-emitting devices include a plurality of red light-emitting devices, a plurality of green light-emitting devices and a plurality of blue light-emitting devices. A ratio of a sum of light exit areas of the plurality of blue light-emitting devices to an area of the display region of the display panel is greater than or equal to 4% and less than or equal to 25%.

In some embodiments, the ratio of the sum of the light exit areas of the plurality of blue light-emitting devices to the area of the display region of the display panel is greater than or equal to 5% and less than or equal to 18%.

In some embodiments, the ratio of the sum of the light exit areas of the plurality of blue light-emitting devices to the area of the display region of the display panel satisfies a following formula 1:

$$\frac{0.15 L}{{J}_{B} [ 50 - {RO}_{B} ( {J}_{B} - 50 ) ] f} \leq SB .$$

In the formula 1, SB represents the ratio of the sum of the light exit areas of the plurality of blue light-emitting devices to the area of the display region of the display panel; L represents a maximum operating luminance of the blue light-emitting devices under a first operating condition; J_{B} represents a current density of the blue light-emitting devices under the first operating condition; RO_{B} represents a ratio of decrease in a current efficiency of the blue light-emitting devices in a case where the current density of the blue light-emitting devices is increased from 5 mA/cm² to 10 mA/cm²; f represents a maximum value of an external quantum efficiency of the blue light-emitting devices that is defined as a maximum value of a ratio of a number of photons radiated by the blue light-emitting devices to a number of hole-electron pairs recombined in the blue light-emitting devices. The first operating condition is an operating condition in which, for chromaticity coordinates of white light emitted by the display panel, an abscissa value is greater than or equal to 0.30 and less than or equal to 0.33, and an ordinate value is greater than or equal to 0.31 and less than or equal to 0.34, and a service life of the blue light-emitting devices is greater than or equal to 300 h.

In some embodiments, a ratio of a sum of light exit areas of the plurality of green light-emitting devices to a sum of light exit areas of the plurality of red light-emitting devices is greater than 1 and less than or equal to 4.

In some embodiments, a ratio of a sum of light exit areas of the plurality of green light-emitting devices to a sum of light exit areas of the plurality of red light-emitting devices is greater than 1 and less than or equal to 3.

In some embodiments, a ratio of a sum of light exit areas of the plurality of green light-emitting devices to a sum of light exit areas of the plurality of red light-emitting devices satisfies a following formula 2:

$$\frac{2.833 {E}_{R} ( 1 - {RO}_{R} )}{{E}_{G} ( 1 - {RO}_{G} )} \leq \frac{SG}{SR} \leq \frac{3.043 {E}_{R} ( 1 - {RO}_{R} )}{{E}_{G} ( 1 - {RO}_{G} ) {k}_{lim}} .$$

In the formula 2, SG represents a ratio of the sum of the light exit areas of the plurality of green light-emitting devices to the area of the display region of the display panel; SR represents a ratio of the sum of the light exit areas of the plurality of red light-emitting devices 21 to the area of the display region of the display panel; E_{G} represents a current efficiency of the green light-emitting devices in a case where a current density of the green light-emitting devices is 10 mA/cm²; E_{R} represents a current efficiency of the red light-emitting devices in a case where a current density of the red light-emitting devices is 10 mA/cm²; RO_{G} represents a ratio of decrease in the current efficiency of the green light-emitting devices in a case where the current density of the green light-emitting devices is increased from 10 mA/cm² to 20 mA/cm²; RO_{R} represents a ratio of decrease in the current efficiency of the red light-emitting devices in a case where the current density of the red light-emitting devices is increased from 10 mA/cm² to 20 mA/cm²; kₗᵢₘ represents a maximum value of a ratio of an operating current of the green light-emitting devices to an operating current of the red light-emitting devices under a second operating condition. The second working condition is an operating condition in which an operating luminance of the display panel is greater than or equal to 100 nit and less than or equal to 800 nit, and for chromaticity coordinates of white light emitted by the display panel, an abscissa value is greater than or equal to 0.30 and less than or equal to 0.33, and an ordinate value is greater than or equal to 0.31 and less than or equal to 0.34.

In some embodiments, a blue light-emitting device includes at least one blue light-emitting layer. A light-emitting material of the blue light-emitting layer includes a metal complex. The metal complex includes at least one of metal ligand elements of platinum, palladium, iridium, gold, nickel, silver, copper or cerium.

In some embodiments, the display panel further includes a pixel definition layer. The pixel definition layer is located on the base substrate. The pixel definition layer is provided with a plurality of light-emitting openings therein, and the plurality of light-emitting openings include a plurality of first light-emitting openings, a plurality of second light-emitting openings and a plurality of third light-emitting openings; a red light-emitting device covers a first light-emitting opening, a green light-emitting device covers a second light-emitting opening, and a blue light-emitting device covers a third light-emitting opening.

A ratio of a sum of areas of the plurality of first light-emitting openings to a sum of areas of the plurality of second light-emitting openings is substantially the same as a ratio of a sum of light exit areas of the plurality of red light-emitting devices to a sum of light exit areas of the plurality of green light-emitting devices.

In some embodiments, a ratio of the sum of the areas of the plurality of first light-emitting openings to a sum of areas of the plurality of third light-emitting openings is substantially the same as a ratio of a sum of light exit areas of the plurality of red light-emitting devices to the sum of the light exit areas of the plurality of blue light-emitting devices.

In some embodiments, a ratio of the sum of the areas of the plurality of second light-emitting openings to the sum of the areas of the plurality of third light-emitting openings is substantially the same as a ratio of the sum of the light exit areas of the plurality of green light-emitting devices to the sum of the light exit areas of the plurality of blue light-emitting devices.

In some embodiments, a ratio of a sum of light exit areas of the plurality of green light-emitting devices to the area of the display region of the display panel is greater than a ratio of a sum of light exit areas of the plurality of red light-emitting devices to the area of the display region of the display panel. The ratio of the sum of the light exit areas of the plurality of blue light-emitting devices to the area of the display region of the display panel is greater than the ratio of the sum of the light exit areas of the plurality of red light-emitting devices to the area of the display region of the display panel.

In some embodiments, a ratio of a sum of light exit areas of the plurality of red light-emitting devices to the sum of the light exit areas of the plurality of blue light-emitting devices is greater than or equal to 0.4 and less than or equal to 0.8.

In some embodiments, a ratio of a sum of light exit areas of the plurality of green light-emitting devices to the sum of the light exit areas of the plurality of blue light-emitting devices is greater than or equal to 0.8 and less than or equal to 1.5.

In some embodiments, a ratio of the sum of the light exit areas of the plurality of blue light-emitting devices to a sum of light exit areas of the plurality of green light-emitting devices and light exit areas of the plurality of red light-emitting devices is greater than or equal to 0.4 and less than or equal to 0.8.

In some embodiments, the display region includes light-emitting regions of the plurality of light-emitting devices and a non-light-emitting region except for the light-emitting regions of the plurality of light-emitting devices. A ratio of the sum of the light exit areas of the plurality of blue light-emitting devices to an area of the non-light-emitting region is greater than or equal to 4% and less than or equal to 75%.

In some embodiments, the display panel further includes a pixel definition layer. The pixel definition layer is located on the base substrate and provided with a plurality of light-emitting openings therein.

A ratio of a sum of areas of the plurality of light-emitting openings to the area of the non-light-emitting region is greater than or equal to 0.2 and less than or equal to 2.0.

In some embodiments, a ratio of the sum of the areas of the plurality of light-emitting openings to the area of the display region of the display panel is greater than or equal to 0.15 and less than or equal to 0.65.

In some embodiments, the display panel further includes an anti-reflective layer. The anti-reflective layer is located on a side of the light-emitting unit away from the base substrate and is configured to deflect light emitted by the light-emitting devices towards a direction perpendicular to the base substrate.

In some embodiments, the display panel further includes an optical functional layer. The optical functional layer is located between the light-emitting unit and the anti-reflection layer and is configured to refract the light emitted by the light-emitting devices to enable the light to be converted into polarized light.

In some embodiments, the display panel further includes a light gain layer. The light gain layer is located between the light-emitting unit and the optical functional layer. The light gain layer includes at least one of a red light gain layer, a green light gain layer and a blue light gain layer that are sequentially stacked in the direction perpendicular to the base substrate.

In another aspect, a display panel is provided. The display panel includes a display region and a non-display region. The display panel includes a base substrate, a pixel definition layer and a light-emitting unit. The pixel definition layer is located on the base substrate, and the pixel definition layer is provided with a plurality of first light-emitting openings, a plurality of second light-emitting openings and a plurality of third light-emitting openings therein. The light-emitting unit includes a plurality of light-emitting devices, and the plurality of light-emitting devices include a plurality of first color light-emitting devices, a plurality of second color light-emitting devices and a plurality of third color light-emitting devices; a first color light-emitting device covers a first light-emitting opening, a second color light-emitting device covers a second light-emitting opening, and a third color light-emitting device covers a third light-emitting opening.

A ratio of a sum of areas of the plurality of third light-emitting openings to an area of the display region of the display panel is greater than or equal to 4% and less than or equal to 25%.

In some embodiments, the ratio of the sum of the areas of the plurality of third light-emitting openings to the area of the display region of the display panel satisfies a following formula 1:

$$\frac{0.15 L}{{J}_{B} [ 50 - {RO}_{B} ( {J}_{B} - 50 ) ] f} \leq SB .$$

In the formula 1, SB represents the ratio of the sum of the areas of the plurality of third light-emitting openings to the area of the display region of the display panel; L represents a maximum operating luminance of the third color light-emitting devices under a first operating condition; J_{B} represents a current density of the third color light-emitting devices under the first operating condition; RO_{B} represents a ratio of decrease in a current efficiency of the third color light-emitting devices in a case where the current density of the third color light-emitting devices is increased from 5 mA/cm² to 10 mA/cm²; f represents a maximum value of an external quantum efficiency of the third color light-emitting devices that is defined as a maximum value of a ratio of a number of photons radiated by the third color light-emitting devices to a number of hole-electron pairs recombined in the third color light-emitting device. The first operating condition is an operating condition in which, for chromaticity coordinates of white light emitted by the display panel, an abscissa value is greater than or equal to 0.30 and less than or equal to 0.33, and an ordinate value is greater than or equal to 0.31 and less than or equal to 0.34, and a service life of the third color light-emitting devices is greater than or equal to 300 h.

In some embodiments, a ratio of a sum of areas of the plurality of second light-emitting openings to a sum of areas of the plurality of first light-emitting openings satisfies a following formula 2.

$$\frac{2.833 {E}_{R} ( 1 - {RO}_{R} )}{{E}_{G} ( 1 - {RO}_{G} )} \leq \frac{SG}{SR} \leq \frac{3.043 {E}_{R} ( 1 - {RO}_{R} )}{{E}_{G} ( 1 - {RO}_{G} ) {k}_{lim}} .$$

In the formula 2, SG represents a ratio of the sum of the areas of the plurality of second light-emitting openings to the area of the display region of the display panel; SR represents a ratio of the sum of the areas of the plurality of first light-emitting openings to the area of the display region of the display panel; E_{G} represents a current efficiency of the second color light-emitting devices in a case where a current density of the second color light-emitting devices is 10 mA/cm²; E_{R} represents a current efficiency of the first color light-emitting devices in a case where a current density of the first color light-emitting devices is 10 mA/cm²; RO_{G} represents a ratio of decrease in the current efficiency of the second color light-emitting devices in a case where the current density of the second color light-emitting devices is increased from 10 mA/cm² to 20 mA/cm²; RO_{R} represents a ratio of decrease in the current efficiency of the first color light-emitting devices in a case where the current density of the first color light-emitting devices is increased from 10 mA/cm² to 20 mA/cm²; kₗᵢₘ represents a maximum value of a ratio of an operating current of the second color light-emitting devices to an operating current of the first color light-emitting devices under a second operating condition. The second operating condition is an operating condition in which an operating luminance of the display panel is greater than or equal to 100 nit and less than or equal to 800 nit, and for the chromaticity coordinates of white light emitted by the display panel, the abscissa value is greater than or equal to 0.30 and less than or equal to 0.33, and the ordinate value is greater than or equal to 0.31 and less than or equal to 0.34.

In another aspect, a display apparatus is provided. The display apparatus includes a circuit board and the display panel as described in any of the above embodiments. The display panel is located on a side of the circuit board, and the display panel is coupled to the circuit board.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a perspective view of a display panel, in accordance with some embodiments;

FIG. 3 is a sectional view of the display panel in an embodiment shown in FIG. 2 taken along the line A-A′;

FIGS. 4 to 8 are each a diagram showing an arrangement structure of sub-pixels in a display panel, in accordance with some embodiments;

FIGS. 9A and 9B are each a sectional view of the display panel shown in FIG. 2 taken along the line A-A′, in accordance with some embodiments;

FIG. 10 is a structural diagram of a light-emitting device, in accordance with some embodiments; and

FIGS. 11 and 12 are each a structural diagram of a display panel, in accordance with some embodiments.

### DESCRIPTION OF THE INVENTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” below are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled”, “connected”, and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that two or more components are in direct physical or electrical contact with each other. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The use of the phrase “applicable to” or “configured to” herein means an open and inclusive expression, which does not exclude devices that are applicable to or configured to perform additional tasks or steps.

In addition, the use of the phrase “based on” or “according to” is meant to be open and inclusive, since a process, step, calculation or other action that is “based on” or “according to” one or more of the stated conditions or values may, in practice, be based on or according to additional conditions or values exceeding those stated.

As used herein, “plurality” throughout this document does not indicate that the number is the same, only that the number includes at least two.

The term such as “about”, “substantially”, and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°. and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

At present, in OLED display panels, the light-emitting materials of blue light-emitting devices include blue fluorescent light-emitting materials and blue phosphorescent light-emitting materials. Since blue phosphorescent materials have poor stability and short service life, while blue fluorescent materials have good stability, blue fluorescent materials are more widely used in the blue light-emitting devices.

However, the inventors of the present disclosure found through research that: in the blue light-emitting devices, the exciton utilization rate of blue fluorescent light-emitting materials is low, resulting in low luminous efficiency of the blue light-emitting devices in a display panel. Compared with blue fluorescent light-emitting materials, blue phosphorescent light-emitting materials greatly improve the exciton utilization rate to improve the luminous efficiency of the blue light-emitting devices. However, for the blue light-emitting devices made of the blue phosphorescent light-emitting materials, it will accelerate the ionization of the blue phosphorescent light-emitting materials based on the improvement of the luminous efficiency of the blue light-emitting devices, resulting in accelerated decay of the luminous efficiency of the blue light-emitting devices and shortening their service life. In this case, as the OLED display panel is used for a longer time, the display performance difference between the red light-emitting devices, the green light-emitting devices and the blue light-emitting devices will gradually increase, resulting in a color shift phenomenon in the display apparatus with the prolonged use. Moreover, the color shift phenomenon of the display apparatus will gradually worsen, reducing the display effect of the display apparatus.

In light of this, some embodiments of the present disclosure provide a display panel and a display apparatus to resolve the problems. The following will be described, respectively.

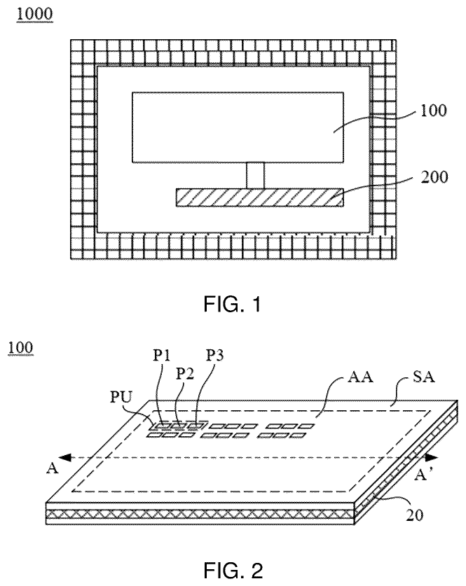

FIG. 1 is a structural diagram of a display apparatus, in accordance with some embodiments.

Referring to FIG. 1, some embodiments of the present disclosure provide a display apparatus 1000. The display apparatus 1000 may be used to display images or pictures. For example, the display apparatus 1000 may be a small and medium sized display apparatus such as a tablet computer, a smart phone, a head-mounted display, an automobile navigation unit, a camera, a central information display (CID) provided in a vehicle, a wristwatch-type display apparatus or any other wearable device, a personal digital assistant (PDA), a portable multimedia player (PMP) or a game console, or a medium and large sized display apparatus such as a television, an external billboard, a monitor, a home appliance including a display screen, a personal computer and a laptop computer. The above electronic devices may be only examples of application of the display apparatus, and a person of ordinary skill in the art can recognize that the display apparatus 1000 may be any other electronic apparatus without departing from the spirit and scope of the present disclosure.

As shown in FIG. 1, the display apparatus 1000 includes a display panel 100 and a circuit board 200, and the display panel 100 is coupled to the circuit board 200. The circuit board 200 is located on a backlight side of the display panel 100, i.e., a side opposite to the display side of the display panel 100. For example, the circuit board 200 may be a flexible printed circuit board (FPC) or a printed circuit board. The circuit board 200 may provide light-emitting data signals, and the display panel 100 emits light based on the light-emitting data signals provided by the circuit board 200.

In some examples, the circuit board 200 may include a processor, a memory, and a timing controller (TCON). The processor may provide image data signals, and the timing controller outputs timing control signals to the display panel 100 based on the image data signals provided by the processor. The processor may be a central processing unit (CPU) or other form of processing device with data processing capabilities and/or instruction execution capabilities. For example, it includes a microprocessor or a programmable logic controller (PLC). The memory may include executable code that is executed by the processor to perform circuit detection tasks.

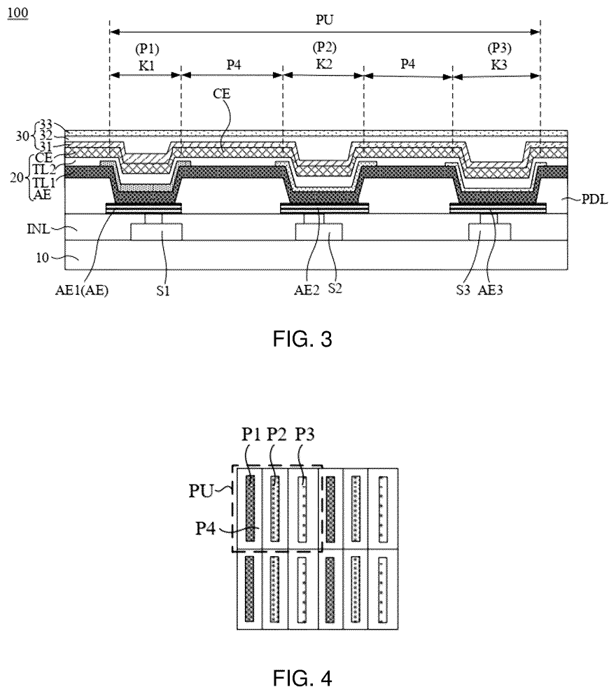

FIG. 2 is a perspective view of a display panel, in accordance with some embodiments; and FIG. 3 is a sectional view of the display panel in an embodiment shown in FIG. 2 taken along the line A-A′.

As shown in FIG. 2, some embodiments of the present disclosure provide a display panel 100. The display panel 100 includes a display region AA for displaying an image and a non-display region SA that does not display an image. The display region AA is an effective display region capable of realizing the display function. The non-display region SA is located on at least one side (e.g., one side; or four sides, including upper and lower sides and left and right sides) of the display region AA. In some examples, the non-display region SA may encircle the display region AA, or may be located outside the display region AA in at least one direction. The display panel 100 in a plan view may be in a shape of rectangle, a circle, an ellipse, a rhombus, a trapezoid, a square or other shape depending on display needs.

For example, the display panel 100 includes a gate driving sub-circuit and a data driving sub-circuit located in the non-display region SA. Based on the image data signals provided by the processor, the timing controller may provide timing control signals to the gate driving sub-circuit and the data driving sub-circuit respectively, so that the gate driving sub-circuit outputs scanning signals and the data driving sub-circuit outputs data signals.

In some embodiments, as shown in FIGS. 2 and 3, the display panel 100 includes a base substrate 10, a light-emitting unit 20 and an encapsulation layer 30. The light-emitting unit 20 is located on a side of the base substrate 10, and the encapsulation layer 30 is located on a side of the light-emitting unit 20 away from the base substrate 10.

The following is a detailed description of the base substrate 10, the light-emitting unit 20 and the encapsulation layer 30 in the display panel 100.

As shown in FIG. 3, the base substrate 10 includes a plurality of pixel unit regions PU that are repeatedly arranged. Each pixel unit region PU includes a first sub-pixel region P1, a second sub-pixel region P2 and a third sub-pixel region P3 that display different colors. For example, the first sub-pixel region P1 is configured to display red light, the second sub-pixel region P2 is configured to display green light, and the third sub-pixel region P3 is configured to display blue light.

In addition, the pixel unit region PU further includes a non-light-emitting region P4. The non-light-emitting region P4 may be located between the first sub-pixel region P1 and the second sub-pixel region P2, between the second sub-pixel region P2 and the third sub-pixel region P3, and between the third sub-pixel region P3 and the first sub-pixel region P1.

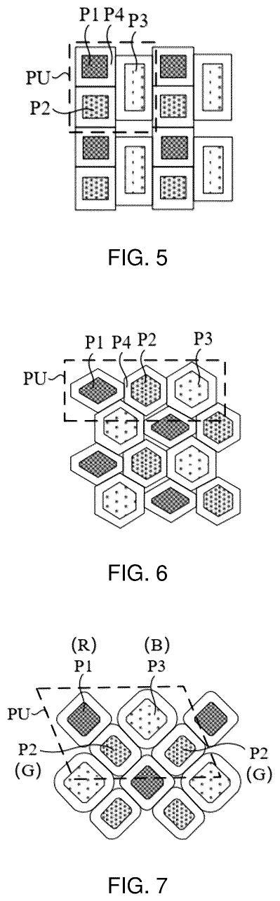

FIGS. 4 to 8 are diagrams each showing an arrangement structure of sub-pixels in a display panel, in accordance with some embodiments.

In some examples, as shown in FIGS. 4 to 6, the pixel unit region PU includes one first sub-pixel region P1, one second sub-pixel region P2 and one third sub-pixel region P3. The first sub-pixel region P1, the second sub-pixel region P2 and the third sub-pixel region P3 are arranged at intervals in a direction perpendicular to the base substrate 10, and they are repeatedly arranged in the display region AA.

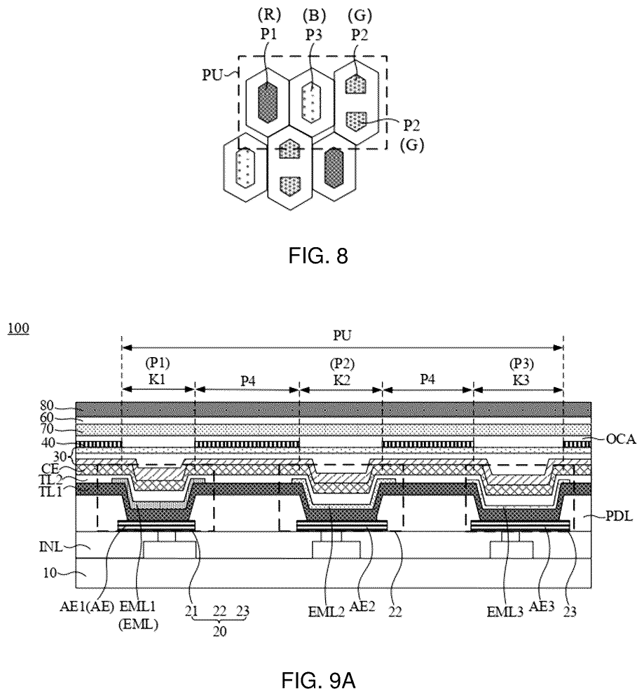

In some examples, as shown in FIGS. 7 and 8, the pixel unit region PU includes two sub-pixel regions displaying the same color, and the two sub-pixel regions displaying the same color may be adjacently arranged. For example, the pixel unit region PU includes one red sub-pixel region R, two green sub-pixel regions G and one blue sub-pixel region B, and the two green sub-pixel regions G in the pixel unit region PU are adjacently arranged.

In some examples, the pixel unit region PU includes one first sub-pixel region P1, two second sub-pixel regions P2 and one third sub-pixel region P3. The one first sub-pixel region P1, the two second sub-pixel regions P2 and the one third sub-pixel region P3 are arranged at intervals, and they are repeatedly arranged in the display region AA. In this case, the non-light-emitting region P4 may also be located between the two second sub-pixel regions P2.

The base substrate 10 may be of a single-layer structure or a laminated composite structure. The base substrate 10 may be a flexible base substrate or a rigid base substrate.

In some examples, the flexible base substrate may be of a laminated composite structure. For example, the flexible base substrate includes a flexible base layer, a barrier layer, and a buffer layer that are stacked in sequence. For another example, the flexible base substrate includes a first flexible base layer, a first barrier layer, a second flexible base layer, a second barrier layer and a buffer layer that are stacked in sequence. The dimensions of the barrier layer, the first barrier layer and the second barrier layer in a direction perpendicular to the display panel 100 are each greater than or equal to 5000 angstroms and less than or equal to 6000 angstroms (e.g., 5000 angstroms, 5200 angstroms, 5500 angstroms, 5800 angstroms or 6000 angstroms). The dimension of the buffer layer in the direction perpendicular to the display panel 100 is greater than or equal to 3500 angstroms and less than or equal to 4500 angstroms (e.g., 3500 angstroms, 3800 angstroms, 4000 angstroms, 4300 angstroms, or 4500 angstroms).

For example, materials of the flexible base layer, the first flexible base layer and the second flexible base layer may each include one or more of polyimide, polyethylene terephthalate, or polycarbonate.

In some other examples, the flexible base substrate may also be of a single-layer structure. For example, the flexible base substrate includes only a flexible base layer.

As shown in FIG. 3, the display panel 100 includes a plurality of pixel circuits located on the base substrate 10. A first pixel circuit S1, a second pixel circuit S2 and a third pixel circuit S3 may be included in the pixel unit region PU. For example, the first pixel circuit S1 is located in the first sub-pixel region P1, the second pixel circuit S2 is located in the second sub-pixel region P2, and the third pixel circuit S3 is located in the third sub-pixel region P3. For another example, thin film transistor(s) in at least one of the first pixel circuit S1, the second pixel circuit S2, and the third pixel circuit S3 may be located in the non-light-emitting region P4.

The structure of the pixel circuit varies, which may be set according to actual needs. For example, the pixel circuit may include at least two transistors (denoted by T) and at least one capacitor (denoted by C). For example, the pixel circuit may have a “2T1C” structure, a “6T1C” structure, a “7T1C” structure, a “6T2C” structure, a “7T2C” structure, or the like.

It will be noted that the transistors used in the embodiments of the present disclosure may be thin film transistors, field effect transistors or other switching devices with same characteristics. Thin film transistors in at least one of the first pixel circuit S1, the second pixel circuit S2 and the third pixel circuit S3 may be thin film transistors including polysilicon or thin film transistors including oxide semiconductors. For example, in a case where the thin film transistors are the thin film transistors including oxide semiconductors, the thin film transistor may have a top-gate thin film transistor structure. The thin film transistors may be connected to signal lines, and the signal lines are, but not limited to, gate lines, data lines and power supply lines. The gate driving sub-circuit may be connected to the pixel circuits through the gate lines to provide various scanning signals, and the data driving sub-circuit may be connected to the pixel circuits through the data lines to provide data signals, so that the pixel circuits drive the light-emitting devices to emit light.

In some examples, the pixel circuit includes a compensation sub-circuit. The compensation sub-circuit may include an internal compensation sub-circuit or an external compensation sub-circuit. The compensation sub-circuit includes a transistor and a capacitor.

In some examples, the pixel circuit may further include a reset circuit, a light-emitting control sub-circuit or a detection circuit.

Specific materials of the pixel circuit may include conductive materials and insulating materials. For example, the conductive material includes gold (Au), silver (Ag), copper (Cu), aluminum (Al), molybdenum (Mo), magnesium (Mg), tungsten (W), alloys composed of the above metals, or conductive metal oxide materials. For example, the conductive metal oxide material may be indium tin oxide (ITO), indium zinc oxide (IZO), zinc oxide (ZnO), or aluminum zinc oxide (AZO). For example, the insulating material includes an inorganic insulating material or organic insulating material. For example, the inorganic insulating material includes silicon oxide, silicon nitride, silicon oxynitride, aluminum oxide or titanium nitride. For example, the organic insulating material may be polyimide, acrylate, epoxy, or polymethylmethacrylate.

As shown in FIG. 3, the display panel 100 includes an insulating layer INL. The insulating layer is located on the first pixel circuit S1, the second pixel circuit S2 and the third pixel circuit S3. The insulating layer INL may have a flat surface. The insulating layer INL may be formed from an organic layer. For example, the insulating layer INL may be made of acrylic resin, epoxy resin, imide resin or ester resin. The insulating layer INL may have through holes for exposing electrodes of the first pixel circuit S1, the second pixel circuit S2 and the third pixel circuit S3, so as to achieve electrical connection.

As shown in FIG. 3, the display panel 100 includes a pixel definition layer PDL located on the base substrate 10. The pixel definition layer PDL may be formed on the insulating layer INL and defines a plurality of light-emitting openings. The plurality of light-emitting openings may include a plurality of first light-emitting openings K1, a plurality of second light-emitting openings K2, and a plurality of third light-emitting openings K3. The plurality of first light-emitting openings K1 may be located in the first sub-pixel regions P1, and the first sub-pixel regions P1 may be red light-emitting regions; the plurality of second light-emitting openings K2 may be located in the second sub-pixel regions P2, and the second sub-pixel regions P2 may be green light-emitting regions; the plurality of third light-emitting openings K3 may be located in the third sub-pixel regions P3, and the third sub-pixel regions P3 may be blue light-emitting regions.

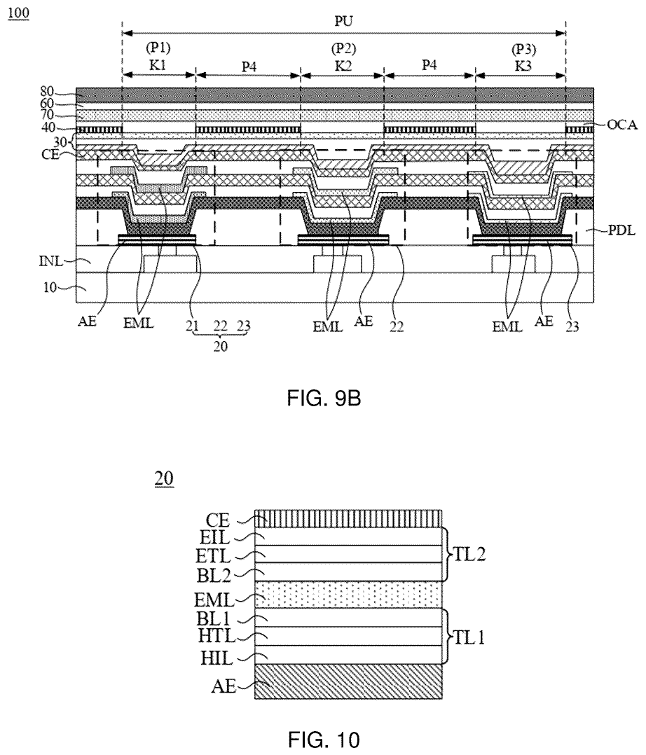

FIGS. 9A and 9B are each a sectional view of the display panel shown in FIG. 2 taken along the line A-A′, in accordance with some embodiments.

As shown in FIGS. 9A and 9B, the light-emitting unit 20 may be located on a side of the insulating layer INL away from the base substrate 10, and the light-emitting unit 20 includes a plurality of light-emitting devices. The plurality of light-emitting devices include a plurality of first color light-emitting devices, a plurality of second color light-emitting devices, and a plurality of third color light-emitting devices.

For example, the first color light-emitting device may be a red light-emitting device 21, the second color light-emitting device may be a green light-emitting device 22, and the third color light-emitting device may be a blue light-emitting device 23.

The light-emitting device may include a first electrode AE, at least one light-emitting layer EML and a second electrode CE that are sequentially stacked in a direction perpendicular to the base substrate 10.

In some examples, the display panel 100 may be a top-emission display panel 100. The first electrode AE is a reflective electrode that capable of reflecting light. For example, the first electrode AE is an anode made of a material with a high work function. The second electrode CE is a transmissive or semi-transmissive electrode that capable of transmitting light. For example, the second electrode CE is a cathode made of a material with a low work function. In this way, a microcavity structure is formed between the anode and the cathode.

As shown in FIG. 9A, the first electrode AE may include a first electrode AE1 located in the first sub-pixel region P1, a first electrode AE2 located in the second sub-pixel region P2, and a first electrode AE3 located in the third sub-pixel region P3.

The first electrode AE may include a laminated composite structure of transparent conductive oxide/metal/transparent conductive oxide. The transparent conductive oxide material may be, for example, ITO or IZO. The metal material may be, for example, at least one of Ag, Mg, Cu, Al, platinum (Pt), palladium (Pd), Au, nickel (Ni), neodymium (Nd), Iridium (Ir), chromium (Cr), lithium (Li), calcium (Ca), lithium fluoride (LiF)/Ca, LiF/Al, Mo, titanium (Ti), indium (In), stannum (Sn), zinc (Zn) or ytterbium (Yb), or oxide thereof. For example, the structure of the anode is of an ITO/Ag/ITO laminated structure.

The second electrode CE may include Ag, Mg, Cu, Al, Pt, Pd, Au, Ni, Nd, Ir, Cr, Li, Ca, LiF/Ca, LiF/Al, Mo or Ti, or a compound or a mixture thereof, such as a mixture of Ag and Mg.

The light-emitting device includes one or more light-emitting layers EML. For example, as shown in FIG. 9B, the light-emitting device may be a laminated light-emitting device including two light-emitting layers EML. For another example, the light-emitting device may be a laminated light-emitting device including three light-emitting layers EML. The description here is only an exemplary description of the light-emitting device and is not intended to limit the solutions of the present disclosure.

FIG. 10 is a structural diagram of a light-emitting device, in accordance with some embodiments.

In some embodiments, as shown in FIG. 10, the light-emitting device may include a first transport layer TL1, a light-emitting layer EML, and a second transport layer TL2. The first transport layer TL1 may be located between the light-emitting layer EML and the first electrode AE, and the first transport layer TL1 is configured to transport holes from the first electrode AE to the light-emitting layer EML. The second transport layer TL2 may be located between the light-emitting layer EML and the second electrode CE, and the second transport layer TL2 is configured to transport electrons from the second electrode CE to the light-emitting layer EML. In this way, the holes and electrons may recombine in the light-emitting layer EML, causing the light-emitting layer EML to emit light.

The first transport layer TL1 and the second transport layer TL2 may each be of a whole layer structure, and the first transport layer TL1 and the second transport layer TL2 may also each be of a patterned structure covering the light-emitting opening. For example, a fine metal mask (FMM) may be used to form the first transport layer TL1 of a patterned structure, the light-emitting layer EML of a patterned structure, the second transport layer TL2 of a patterned structure, and the first electrode AE of a patterned structure, or a photolithography-isolation pillar technology is used to form the first transport layer TL1 of a pattern structure, the light-emitting layer EML of a pattern structure, the second transport layer TL2 of a pattern structure and the first electrode AE of a pattern structure, which is only an illustrative description and is not intended to limit the solutions of the present disclosure.

For example, as shown in FIG. 10, the first transport layer TL1 includes a hole injection layer HIL and a hole transport layer HTL. The hole injection layer HIL is located between the first electrode AE and the hole transport layer HTL, and the hole injection layer HIL is configured to inject holes from the first electrode AE into the hole transport layer HTL. The hole transport layer HTL is located between the hole injection layer HIL and the light-emitting layer EML, and the hole transport layer HTL is configured to transport holes injected by the hole injection layer HIL to the light-emitting layer EML, so that the holes and electrons recombine in the light-emitting layer EML to enable the light-emitting layer EML to emit light.

The material of the hole injection layer HIL may include a P-type dopant and hole transport materials. The P-type dopant may include any one or more of dipyrazino[2,3-f: 2′,3′-h]quinoxaline-2,3,6,7,10,11-hexacarbonitrile, 2,3,5,6-tetrafluoro-7,7,8,8-tetracyanoquinodimethane (F4TCNQ), 1,2,3-tris[(cyano)(4-cyano-2,3,5,6-tetrafluorophenyl)methylene]cyclopropane. In different light-emitting devices, the materials of the hole injection layers HIL may be the same or different.

The material of the hole transport layer HTL and the hole transport material may both include any one or more of arylamine-based hole transport materials, dimethylfluorene-based hole transport materials, and carbazole-based hole transport materials. In different light-emitting devices, the materials of the hole transport layers HTL may be the same or different.

For example, the hole transport material may include any one or more of 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluoren-9-yl) triphenylamine (BAFLP), 4,4′-bis[N-(9,9-dimethylfluoren-2-yl)-N-phenylamino]biphenyl (DFLDPBi), 4,4′-bis(9-carbazolyl) biphenyl (CBP) and 9-phenyl-3-[4-(10-phenyl-9-anthracenyl)phenyl]-9H-carbazole (PCzPA).

In some examples, as shown in FIG. 10, the first transport layer TL1 further includes a first exciton blocking layer BL1. The first exciton blocking layer BL1 may be located between the hole transport layer HTL and the light-emitting layer EML, and the first exciton blocking layer BL1 is configured to block electrons in the light-emitting layer EML from moving in a direction proximate to the first electrode AE. Therefore, the first exciton blocking layer BL1 may also be referred as the electron blocking layer EBL.

The material of the electron blocking layer EBL may include any one or more of arylamine-based electron blocking materials, dimethylfluorene-based electron blocking materials, or carbazole-based electron blocking materials. For example, the material of the electron blocking layer EBL includes any one or more of NPB, TPD, BAFLP, DFLDPBi, CBP and PCzPA. In different light-emitting devices, the materials of the electron blocking layers EBL may be the same or different.

In some examples, as shown in FIG. 10, the second transport layer TL2 may include an electron injection layer EIL and an electron transport layer ETL. The electron injection layer EIL is located between the electron transport layer ETL and the second electrode CE, and the electron injection layer EIL is configured to inject electrons provided by the second electrode CE into the electron transport layer ETL. The electron transport layer ETL is located between the electron injection layer EIL and the light-emitting layer EML. The electron transport layer ETL is configured to transport electrons injected by the electron injection layer EIL to the light-emitting layer EML, so that the electrons and holes recombine in the light-emitting layer EML to enable the light-emitting layer EML to emit light.

The materials of the electron injection layer EIL may include oxides and halides of alkali metals, alkaline earth metals, or other materials with strong electron injection capabilities. For example, the material of the electron injection layer EIL may include 8-hydroxyquinoline (Alq3), lithium oxide (Li₂O), calcium oxide (CaO), cesium oxide (Cs₂O) or Cesium fluoride (CsF).

The material of the electron transport layer ETL may include triazine-based materials with high electron mobility, or other materials with high electron mobility.

In some examples, as shown in FIG. 10, the second transport layer F4 may further include a second exciton blocking layer BL2. The second exciton blocking layer BL2 may be located between the electron transport layer ETL and the light-emitting layer EML, and the second exciton blocking layer BL2 is configured to block holes in the light-emitting layer EML from moving in a direction proximate to the second electrode CE. Therefore, the second exciton blocking layer BL2 may also be referred as the hole blocking layer HBL.

The material of the hole blocking layer HBL may include hole blocking materials of aromatic heterocyclic. For example, aromatic heterocyclic hole blocking materials include any one or more of hole blocking materials of benzimidazole and its derivatives, hole blocking materials of imidazopyridine and its derivatives, hole blocking materials of benziimidazophenanthridine derivatives, hole blocking materials of pyrimidine and its derivatives, hole blocking materials of triazine derivatives, hole blocking materials of pyridine and its derivatives, hole blocking materials of pyrazine and its derivatives, hole blocking materials of quinoxaline and its derivatives, hole blocking materials of diazole and its derivatives, hole blocking materials of quinoline and its derivatives, hole blocking materials of isoquinoline derivatives, hole blocking materials of phenanthroline derivatives, hole blocking materials of diazophosphorene, hole blocking materials of phosphine oxide, hole blocking materials of aromatic ketone, hole blocking materials of lactam or borane. For example, the material of the hole blocking layer HBL includes any one or more of 2-(4-biphenyl)-5-(4-tert-butylphenyl)-1,3,4-oxadiazole (PBD), 1,3-Bis[5-(p-tert-butylphenyl)-1,3,4-oxadiazol-2-yl]benzene (OXD-7), 3-(4-tert-buthylphenyl)-4-phenyl-5-(4-biphenylyl)-1,2,4-triazole (TAZ), 3-(4-tert-buthylphenyl)-4-(4-ethylpheyl)-5-(4-biphenylyl)-1,2,4-triazole (p-EtTAZ), biphenanthroline (BPhen), bathocuproin (BCP) or 4,4′-bis(5-methylbenzoxazole-2-yl) stilbene (BzOs).

The material of the light-emitting layer EML may include one light-emitting material, or may include two or more light-emitting materials. For example, the material of the light-emitting layer EML includes a host material and a guest material, and the guest material may be doped into the host material to emit light. The material of the light-emitting layer EML may also include a light-emitting material with thermally activated delayed fluorescence characteristics at room temperature, a light-emitting material with fluorescence characteristics at room temperature, or a light-emitting material with phosphorescence characteristics at room temperature.

In some examples, as shown in FIG. 9A, the red light-emitting device 21 includes at least one red light-emitting layer EML1. It will be understood that the number of red light-emitting layers EML1 may be one or more. The multiple red light-emitting layers EML1 may be sequentially stacked in the direction perpendicular to the base substrate 10. The light-emitting material of the red light-emitting layer EML1 may include any one or more of red light-emitting materials of 4-(dicyanomethylene)-2-methyl-6-(4-dimethylaminostyryl)-4H-pyran (DCM) and red light-emitting materials of metal complex.

For example, the light-emitting material of the red light-emitting layer EML1 includes any one or more of DCM, 4-(dicyanomethylene)-2-tert-butyl-6-(1,1,7,7-tetramethyljulolidin-4-yl-vinyl)-4H-pyran (DCJTB), bis(1-phenyl-isoquinoline) (acetylacetonato) iridium(III) (Ir(piq)2(acac)), octaethylporphyrin (PtOEP) or platinum(II) bis[2-(2′-benzothienyl)pyridinato-N,C3′](acetylacetonato) iridium (Ir(btp)2(acac)).

In some examples, as shown in FIGS. 9A and 9B, the green light-emitting device 22 includes at least one green light-emitting layer EML2. It will be understood that the number of green light-emitting layers EML2 may be one or more. The multiple green light-emitting layers EML2 may be sequentially stacked in the direction perpendicular to the base substrate 10. The light-emitting materials of the green light-emitting layer EML2 may include any one or more of coumarin dyes, green light-emitting materials of quinacridone derivatives, green light-emitting materials of polycyclic aromatic hydrocarbons, green light-emitting materials of diaminoanthracene derivatives, green light-emitting materials of carbazole derivatives or green light-emitting materials of metal complex.

For example, the light-emitting material of the green light-emitting layer EML2 includes any one or more of coumarin 6 (C-6), coumarin 545T (C-545T), quinacridone (QA), N,N′-dimethylquinacridone (DMQA), 5,12-diphenyltetracene (DPT), N10,N10′-diphenyl-N10,N10′-dinaphthalenyl-9,9′-bianthracene-10,10′-diamine (BA-NPB), Alq3, tris(2-phenylpyridine) iridium(III) (Ir(ppy)3) or bis[2-(2-pyridinyl-N)phenyl-C] (acetylacetonato) iridium(III) (Ir(ppy)2(acac)).

In some embodiments, as shown in FIGS. 9A and 9B, the blue light-emitting device 23 includes at least one blue light-emitting layer EML3. It will be understood that the number of blue light-emitting layers EML3 may be one or more. The blue light-emitting device 23 may be a laminated light-emitting device including a plurality of blue light-emitting layers EML3, and the plurality of blue light-emitting layers EML3 may be sequentially arranged in the direction perpendicular to the base substrate 10.

The light-emitting materials of the blue light-emitting layer EML3 may include any one or more of blue light-emitting materials of pyrene derivatives, blue light-emitting materials of anthracene derivatives, blue light-emitting materials of fluorene derivatives, blue light-emitting materials of perylene derivatives, blue light-emitting materials of styrylamine derivatives and blue light-emitting materials of metal complex. The blue light-emitting material of metal complex may include at least one of metal ligand elements of platinum, palladium, iridium, gold, nickel, silver, copper or cerium. For example, the blue light-emitting material of metal complex may include a metal ligand element of platinum. As another example, the blue light-emitting material of metal complex may include metal ligand elements of copper and cerium.

For example, the light-emitting material of the blue light-emitting layer EML3 includes any one or more of N1,N6-bis([1,1′-biphenyl]-2-yl)-N1,N6-bis([1,1′-biphenyl]-4-yl) pyrene-1,6-diamine, 9,10-di(2-naphthyl) anthracene (ADN), 2-methyl-9,10-di-2-naphthylanthracene (MADN), 2,5,8,11-tetratert-butylperylene (TBPe), 4,4′-bis[4-(diphenylamino) styryl]biphenyl (BDAVBi), 4,4′-bis[4-(di-p-tolylamino) styryl]biphenyl (DPAVBi), bis[2-(4,6-difluorophenyl)pyridine-C2,N](picolinato) iridium(III) (Flrpic), 3-methyl-1-(3-{[9-(pyridin-2-yl) carbazol-2-yl]oxy}phenyl)-2,3-dihydro-1H-benzo[d]imida zole-2-ylidene carbene platinum(II), 9-(pyridin-2-yl)-2-[2-(pyridin-2-yl) carbazol-9-yl]carbazole palladium(II), di-[2,6-difluoro-3-[4-(trimethylsilyl)pyridin-2-yl]pyridine]-2-[5-(trifluoromethyl)-2H-1,2,4-triazacy clo pentyl-3-yl]pyridinium iridium(II), 2,6-bis(2,4-difluorophenyl)-4-(dimethylamino)pyridine-triphenylamine alloy(III), tris-[trans-di-phenylethylene] nickel (0), 2-(5-methyl-1,3,4-thiadiazole)-ethyl sulfoxide 4-4′-di-tert-butyl-bipyridyl silver(I), 2,6-bis(2,4-difluorophenyl)-4-(dimethylamino)pyridine-phenylcarbazole copper(II) or bis-(μ-oxy)tetrakis-[1-{[bis(3,5-dimethylpyrazol-1-yl)](methyl)-λ4-boryl}-3,5-dimethylpyra zole] dicerium(III).

In some examples, the light-emitting material of the blue light-emitting layer EML3 may be a metal complex including metal ligand element of platinum, such as 3-methyl-1-(3-{[9-(pyridin-2-yl) carbazol-2-yl]oxy}phenyl)-2,3-dihydro-1H-benzo[d]imida zole-2-ylidene carbene platinum(II). The energy gap between the lowest unoccupied molecular orbital (LUMO) and the highest occupied molecular orbital (HOMO) of the blue light-emitting material of metal complex is narrow, the minimum energy level difference between the singlet and triplet states that excites the carriers is small, and the blue light-emitting material of metal complex has a good hole transmission performance and electron transmission performance. Therefore, by using the blue light-emitting material of metal complex, the luminous efficiency of the blue light-emitting devices 23 may be improved.

In some embodiments, as shown in FIGS. 3, 9A and 9B, the plurality of light-emitting devices respectively cover the plurality of light-emitting openings, and the plurality of light-emitting devices are connected to the plurality of pixel circuits in a one-to-one correspondence. The first color light-emitting device covers the first light-emitting opening, the second color light-emitting device covers the second light-emitting opening, and the third color light-emitting device covers the third light-emitting opening.

The plurality of light-emitting devices may include a plurality of red light-emitting devices 21, a plurality of green light-emitting devices 22 and a plurality of blue light-emitting devices 23. The red light-emitting device 21 may cover the first light-emitting opening K1, the green light-emitting device 22 may cover the second light-emitting opening K2, and the blue light-emitting device 23 may cover the third light-emitting opening K3.

In some embodiments, a ratio of a sum of areas of the plurality of light-emitting openings to an area of the display region AA of the display panel 100 is greater than or equal to 0.15 and less than or equal to 0.65 (e.g., 0.15, 0.18, 0.20, 0.22, 0.25, 0.35, 0.40, 0.45, 0.50, 0.55, 0.60 or 0.65).

By setting the ratio of the sum of the areas of the plurality of light-emitting openings to the area of the display region AA of the display panel 100 to be in an appropriate range, the effective light-emitting area of the plurality of light-emitting devices in the display panel 100 may be increased, thereby improving the luminous efficiency of the plurality of light-emitting devices in the display panel 100.

In some embodiments, a ratio of a sum of areas of the plurality of third light-emitting openings K3 to the area of the display region AA of the display panel 100 is greater than or equal to 4% and less than or equal to 25% (e.g., 4%, 6%, 8%, 10%, 12%, 15%, 17%, 18%, 20%, 22% or 25%).

By setting the ratio of the sum of the areas of the plurality of third light-emitting openings K3 to the area of the display region AA of the display panel 100 to be in an appropriate range, the effective light-emitting area of the third light-emitting openings K3 covering the corresponding third color light-emitting devices in the display panel 100 may be improved, thereby improving the luminous efficiency and display luminance of the third color light-emitting device. As a result, it is possible to reduce the ratio of attenuation in the luminance of the third color light-emitting devices in the display panel 100 over time, thereby ameliorating the color shift phenomenon of the display panel 100 to improve the display effect of the display apparatus 1000.

In some examples, a ratio of a sum of areas of the plurality of second light-emitting openings K2 to a sum of areas of the plurality of first light-emitting openings K1 is greater than 1 and less than or equal to 4 (e.g., 1.1, 1.5, 1.8, 2.0, 2.3, 2.5, 2.8, 3, 3.5, 3.8 or 4).

In some examples, a ratio of the sum of the areas of the plurality of first light-emitting openings K1 to the sum of the areas of the plurality of third light-emitting openings K3 is greater than or equal to 0.4 and less than or equal to 0.8 (e.g., 0.4, 0.5, 0.6, 0.7, or 0.8).

In some examples, a ratio of the sum of the areas of the plurality of second light-emitting openings K2 to the sum of the areas of the plurality of third light-emitting openings K3 is greater than or equal to 0.8 and less than or equal to 1.5 (e.g., 0.8, 0.9, 1.0, 1.2, 1.4 or 1.5).

In some examples, a ratio of the sum of the areas of the plurality of third light-emitting openings K3 to a sum of the areas of the plurality of first light-emitting openings K1 and the areas of the plurality of second light-emitting openings K2 is greater than or equal to 0.4 and less than or equal to 0.8 (e.g., 0.4, 0.5, 0.6, 0.7 or 0.8).

In some embodiments, the ratio of the sum of the areas of the plurality of third light-emitting openings K3 to the area of the display region AA of the display panel 100 satisfies a following formula 1:

$$\frac{0.15 L}{{J}_{B} [ 50 - {RO}_{B} ( {J}_{B} - 50 ) ] f} \leq SB .$$

In the formula 1, SB represents the ratio of the sum of the areas of the plurality of third light-emitting openings K3 to the area of the display region AA of the display panel 100; L represents the maximum operating luminance of the third color light-emitting devices under a first operating condition; J_{B} represents a current density of the third color light-emitting devices under the first operating condition, in A/m²; RO_{B} represents a ratio of decrease in the current efficiency of the third color light-emitting devices in a case where the current density of the third color light-emitting devices is increased from 5 mA/cm² to 10 mA/cm²; f represents a maximum value of an external quantum efficiency (EQE) of the third color light-emitting devices that is defined as a maximum value of a ratio of the number of photons radiated by the third color light-emitting devices to the number of hole-electron pairs recombined in the third color light-emitting device; the first operating condition is an operating condition in which, for chromaticity coordinates of white light emitted by the display panel, an abscissa value is greater than or equal to 0.30 and less than or equal to 0.33 (e.g., 0.30, 0.31, 0.32 or 0.33), and an ordinate value is greater than or equal to 0.31 and less than or equal to 0.34 (e.g., 0.31, 0.32, 0.33 or 0.34), and the service life of the third color light-emitting devices is greater than or equal to 300 h (e.g., 300 h, 320 h, 350 h, 380 h or 400 h).

The service life of the third color light-emitting devices is a time LT95 required for the luminance of the third color light-emitting devices to decay to 95% in a state that the display panel 100 emits white light with a specific initial luminance.

RO_{B} is calculated through RO_{B}=(E−E′)/E, where E is the current efficiency of the third color light-emitting devices in a case where the current density of the third color light-emitting devices is 5 mA/cm², in cd/A; E′ is the current efficiency of the third color light-emitting devices in a case where the current density of the third color light-emitting devices is 10 mA/cm², in cd/A.

In this way, the ratio SB of the sum of the areas of the plurality of third light-emitting openings K3 to the area of the display region AA of the display panel 100 is calculated by the formula 1, so that it is possible to maximize the effective light-emitting area of the plurality of third color light-emitting devices in the display panel 100 on the basis of ensuring and limiting the attenuation rate of the luminous efficiency of the third color light-emitting device. Thus, the luminous efficiency and display luminance of the third color light-emitting devices is improved, which reduces the ratio of attenuation in the luminance of the third color light-emitting devices in the display panel 100 over time, thereby ameliorating the color shift phenomenon of the display panel 100 to improve the display effect of the display apparatus 1000.

In some embodiments, a ratio of a sum of areas of the plurality of second light-emitting openings K2 to a sum of areas of the plurality of first light-emitting openings K1 satisfies a following formula 2:

$$\frac{2.833 {E}_{R} ( 1 - {RO}_{R} )}{{E}_{G} ( 1 - {RO}_{G} )} \leq \frac{SG}{SR} \leq \frac{3.043 {E}_{R} ( 1 - {RO}_{R} )}{{E}_{G} ( 1 - {RO}_{G} ) {k}_{lim}} .$$

In the formula 2, SG represents a ratio of the sum of the areas of the plurality of second light-emitting openings K2 to the area of the display region AA of the display panel 100; SR represents a ratio of the sum of the areas of the plurality of first light-emitting openings K1 to the area of the display region AA of the display panel 100; E_{G} represents the current efficiency of the second color light-emitting devices in a case where the current density of the second color light-emitting devices is 10 mA/cm², in cd/A; E_{R} represents the current efficiency of the first color light-emitting devices in a case where the current density of the first color light-emitting devices is 10 mA/cm², in cd/A; RO_{G} represents a ratio of decrease in the current efficiency of the second color light-emitting devices in a case where the current density of the second color light-emitting devices is increased from 10 mA/cm² to 20 mA/cm²; RO_{R} represents a ratio of decrease in the current efficiency of the first color light-emitting devices in a case where the current density of the first color light-emitting devices is increased from 10 mA/cm² to 20 mA/cm²; kₗᵢₘ represents a maximum value of a ratio of an operating current of the second color light-emitting devices to an operating current of the first color light-emitting devices under a second operating condition.

The second operating condition is an operating condition in which the operating luminance of the display panel 100 is greater than or equal to 100 nit and less than or equal to 800 nit (e.g., 100 nit, 200 nit, 400 nit, 600 nit or 800 nit), and for the chromaticity coordinates of the white light emitted by the display panel, the abscissa value is greater than or equal to 0.30 and less than or equal to 0.33 (e.g., 0.30, 0.31, 0.32 or 0.33), and the ordinate value is greater than or equal to 0.31 and less than or equal to 0.34 (e.g., 0.31, 0.32, 0.33 or 0.34).

In this way, by calculating the ratio of the sum of the areas of the plurality of second light-emitting openings K2 to the sum of the areas of the plurality of first light-emitting openings K1 by the formula 2, the ratio of attenuation in the luminous efficiency of the first color light-emitting device, the ratio of attenuation in the luminous efficiency of the second color light-emitting device, and the ratio of the operating current of the second color light-emitting devices to the operating current of the first color light-emitting devices may be accurately limited, so that the ratio of attenuation in the luminance of the first color light-emitting devices in the display panel 100 over time is close to the ratio of attenuation in the luminance of the second color light-emitting devices in the display panel 100 over time. Moreover, by setting the operating condition in which the chromaticity coordinates of the white light emitted by the display panel 100 are the same, in the same display panel 100, both the ratio of attenuation in the luminance of the first color light-emitting devices over time and the ratio of attenuation in the luminance of the second color light-emitting devices over time may match the ratio of attenuation in the luminance of the third color light-emitting devices over time, thereby ensuring that the color gamut of the display panel 100 100% covers the national television standards committee (NTSC) color gamut standard, and ameliorating the color shift phenomenon of the display panel 100 to improve the stability of the display performance and the display effect of the display panel 100. A light exit area of a light-emitting device may be understood as an area of a corresponding light-emitting opening covering the light-emitting device. A sum of the light exit areas of the plurality of red light-emitting devices 21 may be understood as a sum of the light exit areas of all the red light-emitting devices 21 in the display panel 100. A sum of the light exit areas of the plurality of green light-emitting devices 22 may be understood as a sum of the light exit areas of all the green light-emitting devices 22 in the display panel 100. A sum of the light exit areas of the plurality of blue light-emitting devices 23 may be understood as a sum of the light exit areas of all the blue light-emitting devices 23 in the display panel 100.

In some examples, a ratio of the sum of the areas of the plurality of first light-emitting openings K1 to the sum of the areas of the plurality of second light-emitting openings K2 is substantially the same as a ratio of the sum of the light exit areas of the plurality of red light-emitting devices 21 to the sum of the light exit areas of the plurality of green light-emitting devices 22.

In this way, the ratio of the areas of the first light-emitting openings K1 to the light exit areas of the red light-emitting devices 21 may be substantially the same as the ratio of the areas of the second light-emitting openings K2 to the light exit areas of the green light-emitting devices 22, so that a ratio of the effective light-emitting areas of the red light-emitting devices 21 defined by the areas of the first light-emitting openings K1 to the light exit areas of the red light-emitting devices 21 is the same as a ratio of the effective light-emitting areas of the green light-emitting devices 22 defined by the areas of the second light-emitting openings K2 to the light exit areas of the green light-emitting devices 22. As a result, it is possible to reduce the difference between the display performance of the red light-emitting devices 21 and the display performance of the green light-emitting devices 22 in the same display panel 100, thereby improving the stability of the display performance of the display panel 100.

In some examples, a ratio of the sum of the areas of the plurality of first light-emitting openings K1 to the sum of the areas of the plurality of third light-emitting openings K3 is substantially the same as a ratio of the sum of the light exit areas of the plurality of red light-emitting devices 21 to the sum of the light exit areas of the plurality of blue light-emitting devices 23.

In this way, the ratio of the areas of the first light-emitting openings K1 to the light exit areas of the red light-emitting devices 21 may be substantially the same as the ratio of the areas of the third light-emitting openings K3 to the light exit areas of the blue light-emitting devices 23, so that the ratio of the effective light-emitting areas of the red light-emitting devices 21 defined by the areas of the first light-emitting openings K1 to the light exit areas of the red light-emitting devices 21 is the same as the ratio of the effective light-emitting areas of the blue light-emitting devices 23 defined by the areas of the third light-emitting openings K3 to the light exit areas of the blue light-emitting devices 23. As a result, it is possible to reduce the difference between the display performance of the red light-emitting devices 21 and the display performance of the blue light-emitting devices 23 in the same display panel 100, thereby improving the stability of the display performance of the display panel 100.

In some examples, a ratio of the sum of the areas of the plurality of second light-emitting openings K2 to the sum of the areas of the plurality of third light-emitting openings K3 is substantially the same as the ratio of the sum of the light exit areas of the plurality of green light-emitting devices 22 to the sum of the light exit areas of the plurality of blue light-emitting devices 23.

In this way, the ratio of the areas of the second light-emitting openings K2 to the light exit areas of the green light-emitting devices 22 may be substantially the same as the ratio of the areas of the third light-emitting openings K3 to the light exit areas of the blue light-emitting devices 23, so that the ratio of the effective light-emitting areas of the green light-emitting devices 22 defined by the areas of the second light-emitting openings K2 to the light exit areas of the green light-emitting devices 22 is the same as the ratio the effective light-emitting areas of the blue light-emitting devices 23 defined by the areas of the third light-emitting openings K3 to the light exit areas of the blue light-emitting devices 23. As a result, it is possible to reduce the difference between the display performance of the green light-emitting devices 22 and the display performance of the blue light-emitting devices 23 in the same display panel 100, thereby improving the stability of the display performance of the display panel 100.

In some embodiments, a ratio of the sum of the light exit areas of the plurality of blue light-emitting devices 23 to the area of the display region of the display panel 100 is greater than or equal to 4% and less than or equal to 25% (e.g., 4%, 6%, 8%, 10%, 12%, 15%, 17%, 18%, 20%, 22% or 25%).

By limiting the ratio of the sum of the light exit areas of the plurality of blue light-emitting devices 23 to the area of the display region of the display panel 100 to an appropriate range, the effective light-emitting areas of the plurality of blue light-emitting devices 23 in the display panel 100 may be increased, thereby improve the luminous efficiency of the blue light-emitting devices 23 and the display brightness of blue light in the display panel 100. Thus, it is possible to reduce the ratio of attenuation in the luminance of the blue light-emitting devices 23 in the display panel 100 over time, thereby ameliorating the color shift phenomenon of the display panel 100 to improve the display effect of the display apparatus 1000.

In some examples, the ratio of the sum of the light exit areas of the plurality of blue light-emitting devices 23 to the area of the display region of the display panel 100 is greater than or equal to 5% and less than or equal to 18% (e.g., 5%, 7%, 9%, 11%, 13%, 15%, 16% or 18%).

By limiting the ratio of the sum of the light exit areas of the plurality of blue light-emitting devices 23 to the area of the display region of the display panel 100 to an appropriate range, the luminous efficiency of the blue light-emitting devices 23 and the display brightness of blue light in the display panel 100 may be greatly improved to ensure the service life of the blue light-emitting devices 23, which reduces the ratio of attenuation in luminous efficiency and service life of the blue light-emitting devices 23 over time, thereby ameliorating the color shift phenomenon of the display panel 100 to improve the display effect of the display apparatus 1000.

In some embodiments, the ratio of the sum of the light exit areas of the plurality of blue light-emitting devices 23 to the area of the display region of the display panel 100 satisfies a following formula 1:

$$\frac{0.15 L}{{J}_{B} [ 50 - {RO}_{B} ( {J}_{B} - 50 ) ] f} \leq SB .$$

In the formula 1, SB represents the ratio of the sum of the light exit areas of the plurality of blue light-emitting devices 23 to the area of the display region of the display panel 100; L represents the maximum operating luminance of the blue light-emitting devices 23 under the first operating condition; J_{B} represents a current density of the blue light-emitting devices 23 under the first operating condition, in A/m²; RO_{B} represents a ratio of decrease in the current efficiency of the blue light-emitting devices in a case where the current density of the blue light-emitting devices is increased from 5 mA/cm² to 10 mA/cm²; f represents a maximum value of the external quantum efficiency of the blue light-emitting devices of the display panel 100 that is defined as a maximum value of a ratio of the number of photons radiated by the blue light-emitting devices to the number of hole-electron pairs recombined in the blue light-emitting device; a wavelength of blue light is greater than or equal to 440 nm and less than or equal to 480 nm (e.g., 440 nm, 460 nm or 480 nm).

The first operating condition is an operating condition in which, for the chromaticity coordinates of the white light emitted by the display panel 100, an abscissa value is greater than or equal to 0.30 and less than or equal to 0.33 (e.g., 0.30, 0.31, 0.32 or 0.33), and an ordinate value is greater than or equal to 0.31 and less than or equal to 0.34 (e.g., 0.31, 0.32, 0.33 or 0.34), and the service life of the blue light-emitting devices 23 is greater than or equal to 300 h (e.g., 300 h, 320 h, 350 h, 380 h or 400 h). The service life of the blue light-emitting devices 23 is the time LT95 required for the luminance of the blue light-emitting devices 23 to decay to 95% in a state that the display panel 100 emits white light with a specific initial luminance.

RO_{B} is calculated by RO_{B}=(E−E′)/E, where E is the current efficiency of the blue light-emitting devices 23 in a case where the current density of the blue light-emitting devices 23 is 5 mA/cm², in cd/A; E′ is the current efficiency of the blue light-emitting devices 23 in a case where the current density of the blue light-emitting devices 23 is 10 mA/cm², in cd/A.

The measurement method of f includes: adjusting the display panel 100 to display a blue image (i.e., only lighting up the plurality of blue light-emitting devices 23 in the display panel 100); then, placing the display panel 100 into an integrating sphere tester, and calibrating a set ratio of the luminous intensity of the blue light-emitting devices 23 to the number of photons radiated by the blue light-emitting devices 23 in the integrating sphere tester; obtaining the value of the luminous intensity of the plurality of blue light-emitting devices 23, emitting light from all directions, in the display panel 100 through the integrating sphere tester; then, obtaining the number n₁ of photons radiated by the plurality of blue light-emitting devices 23 in the display panel 100 through a ratio of the value of the luminous intensity of the plurality of blue light-emitting devices 23, emitting light from all directions, in the display panel 100 through the integrating sphere tester to the set ratio of the luminous intensity of the blue light-emitting devices 23 to the number of photons radiated by the blue light-emitting devices 23 in the integrating sphere tester; then, obtaining the number n₂ of hole-electron pairs recombined in the blue light-emitting devices 23 through the conversion of the external current and power consumption of the display panel 100; and finally, obtaining the maximum value of the measured value of f by calculating n₁/n₂.

In some examples, the determining process of the relevant parameters L and J_{B} of the blue light-emitting devices 23 in the formula 1 may include the following steps. Firstly, in a case where the initial chromaticity coordinate value CIE of the white light of the display panel 100 is (0.30, 0.31), the current density and luminance of the blue light-emitting devices 23 are tested.

Secondly, based on the test data of the current density and luminance of the blue light-emitting devices 23, a curve is drawn in which the abscissa is the current density of the blue light-emitting devices 23 and the ordinate is the luminance of the blue light-emitting devices 23.

Afterwards, in a case where for the chromaticity coordinates of the white light emitted by the display panel 100, the abscissa value is greater than or equal to 0.30 and less than or equal to 0.33 (e.g., 0.30, 0.31, 0.32 or 0.33), and the ordinate value is greater than or equal to 0.31 and less than or equal to 0.34 (e.g., 0.31, 0.32, 0.33 or 0.34), the time LT95 required for the light emission luminance of the blue light-emitting devices 23 to decay to 95% of the initial luminance in a state that emitting whit light with a specific initial luminance (e.g., 1000 nit) is tested. If the chromaticity coordinate values corresponding to the white light emitted by the display panel 100 exceed the respective ranges, the specific initial luminance of the white light must be reduced and the time LT95 is retested.

Until the time LT95 of the blue light-emitting devices 23 satisfies the condition of greater than or equal to 300 h (e.g., 300 h, 320 h, 350 h, 380 h or 400 h), the maximum value (i.e., the value of L) of the operating luminance of the blue light-emitting devices 23 is calculated through the stretched exponential decay (SED) model. The mathematical expression of SED model includes Formulas 3 and 4 below:

$$L = {L}_{0} exp [ - {( \frac{t}{α} )}^{β} ] ; \qquad Formula 3$$

$$C = {L}_{0}^{n} {t}_{95} . \qquad Formula 4$$

In the above Formulas 3 and 4, L represents the relative luminous intensity of the blue light-emitting devices 23 at a specific time t, L₀ is the luminous intensity at the initial time; a represents the characteristic life value, and in the lifetime image of the blue light-emitting devices 23, in a case where t=α, s(t)=exp(−1), and in this case, the abscissa value is α; β represents the characteristic exponent of the blue light-emitting devices 23, β is a constant in a range of 0 to 1, inclusive; t₉₅ is the time LT95, required for the light emission luminance of the blue light-emitting devices 23 to decay to 95% of the initial luminance; C represents the setting value during the test of the light-emitting device; n represents the light emission luminance attenuation factor of the blue light-emitting devices 23, n is related to the structure and material properties of the blue light-emitting devices 23, the light emission luminance of different blue light-emitting devices 23 and the time LT95 may be tested through multiple aging experiments, and n may be calculated through Formula 4.

Then, according to the curve in which the abscissa is the current density of the blue light-emitting devices 23 and the ordinate is the luminance of the blue light-emitting devices 23, the value of the current density of the blue light-emitting devices 23 under the first operating condition is determined.

For example, the value of L is greater than or equal to 100 nit and less than or equal to 800 nit; for example, L is 100 nit, 200 nit, 400 nit, 600 nit or 800 nit. For another example, under the first operating condition, the operating luminance of the blue light-emitting devices 23 may be 400 nit or 800 nit, then the value of L is 800 nit.

In this way, by calculating the ratio SB of the sum of the light exit areas of the plurality of blue light-emitting devices 23 to the area of the display region of the display panel 100 through the formula 1, it is possible to maximize the effective light-emitting areas of the plurality of blue light-emitting devices in the display panel 100 on the basis of ensuring the service life of the blue light-emitting devices 23 and limiting the attenuation rate of the luminous efficiency of the blue light-emitting devices 23, thereby improving the luminous efficiency of the blue light-emitting devices 23 and the display luminance of the blue light emitted by the display panel 100, and reducing the working load of the blue light-emitting devices 23. As a result, it is possible to reduce the ratio of attenuation in the luminance of the blue light-emitting devices 23 over time, thereby ameliorating the color shift phenomenon of the display panel 100 to improve the display effect of the display apparatus 1000.

In some embodiments, the display region AA includes light-emitting regions of the plurality of light-emitting devices, and a non-light-emitting region except for the light-emitting regions of the plurality of light-emitting devices. The area of the light-emitting region of the light-emitting device may be understood as the area corresponding to the light-emitting opening covering the light-emitting device, i.e., the light exit area of the light-emitting device.

A ratio of an area of the non-light-emitting region to the area of the display region of the display panel 100 is greater than or equal to 35% and less than or equal to 82% (e.g., 35%, 40%, 45%, 50%, 55%, 60%, 65%, 70%, 72%, 75%, 78%, 80% or 82%).

In some embodiments, a ratio of a sum of areas of the plurality of light-emitting openings to the area of the non-light-emitting region is greater than or equal to 0.2 and less than or equal to 2.0 (e.g., 0.2, 0.22, 0.25, 0.30, 0.35, 0.4, 0.5, 0.6, 0.7, 0.8, 0.9, 1.2, 1.5, 1.6, 1.8 or 2.0).

By limiting the ratio of the sum of the areas of the plurality of light-emitting openings to the area of the non-light-emitting region to an appropriate range, the effective light-emitting areas of the plurality of light-emitting devices in the display panel 100 may be increased, thereby improving the luminous efficiency of the plurality of light-emitting devices in the display panel 100.

In some embodiments, a ratio of the sum of the light exit areas of the plurality of blue light-emitting devices 23 to the area of the non-emitting region may be greater than or equal to 4% and less than or equal to 75% (e.g., 4%, 8%, 10%, 15%, 20%, 22%, 25%, 28%, 30%, 35%, 40%, 45%, 50%, 55%, 60%, 65%, 70% or 75%).

By limiting the ratio of the sum of the light exit areas of the plurality of blue light-emitting devices 23 to the area of the non-light-emitting region to an appropriate range, the luminance of the blue light emitted by the plurality of blue light-emitting devices 23 in the display panel 100 may be relatively improved, which ameliorates the weak luminance phenomenon of the blue light of the display panel 100 and reduces the ratio of attenuation in the luminance of the blue light-emitting devices 23 in the display panel 100 over time, thereby ameliorating the color shift phenomenon of the display panel 100 to improve the display effect of the display apparatus 1000.

In some embodiments, a ratio of the sum of the light exit areas of the plurality of green light-emitting devices 22 to the sum of the light exit areas of the plurality of red light-emitting devices 21 is greater than 1 and less than or equal to 4 (e.g., 1.1, 1.5, 1.8, 2.0, 2.3, 2.5, 2.8, 3, 3.5, 3.8 or 4).

Since the luminous efficiency of the red light-emitting devices 21 is greater than the luminous efficiency of the green light-emitting devices 22, the light exit areas of the plurality of red light-emitting devices 21 may be relatively reduced by limiting the ratio of the sum of the light exit areas of the plurality of green light-emitting devices 22 to the sum of the light exit areas of the plurality of red light-emitting devices 21. Therefore, the luminance and luminous efficiency of the red light-emitting devices 21 may be relatively reduced, which reduces the difference between the ratio of attenuation in the luminance of the red light-emitting devices 21 over time and the ratio of attenuation in the luminance of the green light-emitting devices 22 over time, thereby ameliorating the color shift phenomenon of the display panel 100 to improve the display effect and the stability of the display performance of the display panel 100.

In some examples, the ratio of the sum of the light exit areas of the plurality of green light-emitting devices 22 to the sum of the light exit areas of the plurality of red light-emitting devices 21 is greater than 1 and less than or equal to 3 (e.g., 1.2, 1.4, 1.7, 2.1, 2.4, 2.6, 2.9 or 3).

By limiting the ratio of the sum of the light exit areas of the plurality of green light-emitting devices 22 to the sum of the light exit areas of the plurality of red light-emitting devices 21 to an appropriate range, the light exit areas of the plurality of red light-emitting devices 21 may be relatively reduced, which further reduces the difference between the ratio of attenuation in the luminance of the red light-emitting devices 21 over time and the ratio of attenuation in the luminance of the green light-emitting devices 22 over time, thereby effectively ameliorating the color shift phenomenon of the display panel 100 to improve the stability of the display performance and the display effect of the display panel 100.

In some embodiments, the ratio of the sum of the light exit areas of the plurality of green light-emitting devices 22 to the sum of the light exit areas of the plurality of red light-emitting devices 21 satisfies the following formula 2:

$$\frac{2.833 {E}_{R} ( 1 - {RO}_{R} )}{{E}_{G} ( 1 - {RO}_{G} )} \leq \frac{SG}{SR} \leq \frac{3.043 {E}_{R} ( 1 - {RO}_{R} )}{{E}_{G} ( 1 - {RO}_{G} ) {k}_{lim}} .$$

In the formula 2, SG represents a ratio of the sum of the light exit areas of the plurality of green light-emitting devices 22 to the area of the display region of the display panel 100; SR represents a ratio of the sum of the light exit areas of the plurality of red light-emitting devices 21 to the area of the display region of the display panel 100; E_{G} represents a current efficiency of the green light-emitting devices 22 in a case where a current density of the green light-emitting devices 22 is 10 mA/cm², in cd/A; E_{R} represents a current efficiency of the red light-emitting devices 21 in a case where a current density of the red light-emitting devices 21 is 10 mA/cm², in cd/A; RO_{G} represents a ratio of decrease in the current efficiency of the green light-emitting devices 22 in a case where the current density of the green light-emitting devices 22 is increased from 10 mA/cm² to 20 mA/cm²; RO_{R} represents a ratio of decrease in the current efficiency of the red light-emitting devices 21 in a case where the current density of the red light-emitting devices 21 is increased from 10 mA/cm² to 20 mA/cm²; kₗᵢₘ represents a maximum value of a ratio of an operating current of the green light-emitting devices 22 to an operating current of the red light-emitting devices 21 under a second operating condition.

The second operating condition is an operating condition in which an operating luminance of the display panel 100 is greater than or equal to 100 nit and less than or equal to 800 nit (e.g., 100 nit, 200 nit, 400 nit, 600 nit or 800 nit), and for the chromaticity coordinates of the white light emitted by the display panel, an abscissa value is greater than or equal to 0.30 and less than or equal to 0.33 (e.g., 0.30, 0.31, 0.32 or 0.33), and an ordinate value is greater than or equal to 0.31 and less than or equal to 0.34 (e.g., 0.31, 0.32, 0.33 or 0.34).

RO_{R} is calculated by RO_{R}=(E_{R}−E_{R}′)/E_{R}, where E_{R}′ is the current efficiency in a case where the current density of the red light-emitting devices 21 is 20 mA/cm², in cd/A.

RO_{G} is calculated by RO_{G}=(E_{G}−E_{G}′)/E_{G}, where E_{G}′ is the current efficiency in a case where the current density of the green light-emitting devices 22 is 20 mA/cm², in cd/A.

In this way, by calculating the ratio of the sum of the light exit areas of the plurality of green light-emitting devices 22 to the sum of the light exit areas of the plurality of red light-emitting devices 21 through the formula 2, the ratio of attenuation in the luminous efficiency of the red light-emitting devices 21, the ratio of attenuation in the luminous efficiency of the green light-emitting devices 22, and the ratio of the operating current of the green light-emitting devices 22 to the operating current of the red light-emitting devices 21 may be accurately limited, so that the ratio of attenuation in the luminance of the red light-emitting devices 21 in the display panel 100 over time is close to the ratio of attenuation in the luminance of the green light-emitting devices 22 in the display panel 100 over time. Moreover, by setting the operating conditions in which the chromaticity coordinates of the white light emitted by the display panel 100 are the same, in the same display panel 100, both the ratio of attenuation in the luminance of the red light-emitting devices 21 over time and the ratio of attenuation in the luminance of the green light-emitting devices 22 over time may match the ratio of attenuation in the luminance of the blue light-emitting devices 23 over time, thereby ensuring that the color gamut of the display panel 100 100% covers the NTSC color gamut standard, and ameliorating the color shift phenomenon of the display panel 100 to improve the stability of the display performance and display effect of the display panel 100.

In some embodiments, the ratio of the sum of the light exit areas of the plurality of red light-emitting devices 21 to the sum of the light exit areas of the plurality of blue light-emitting devices 23 is greater than or equal to 0.4 and less than or equal to 0.8 (e.g., 0.4, 0.5, 0.6, 0.7 or 0.8).

Since the luminous efficiency of the red light-emitting devices 21 is greater than that of the blue light-emitting devices 23, the light exit areas of the plurality of red light-emitting devices 21 may be relatively reduced by limiting the ratio of the sum of the light exit areas of the plurality of red light-emitting devices 21 to the sum of the light exit areas of the plurality of blue light-emitting devices 23. Therefore, the luminance and luminous efficiency of the red light-emitting devices 21 may be relatively reduced, which reduces the difference between the luminous efficiency of the red light-emitting devices 21 and the luminous efficiency of the blue light-emitting devices 23, so that the ratio of attenuation in the luminance of the red light-emitting devices 21 in the display panel 100 over time is close to the ratio of attenuation in the luminance of the blue light-emitting devices 23 in the display panel 100 over time. As a result, the color shift phenomenon of the display panel 100 is ameliorated, and the stability of the display performance and display effect of the display panel 100 are improved.

In some embodiments, the ratio of the sum of the light exit areas of the plurality of green light-emitting devices 22 to the sum of the light exit areas of the plurality of blue light-emitting devices 23 is greater than or equal to 0.8 and less than or equal to 1.5 (e.g., 0.8, 0.9, 1.0, 1.2, 1.4 or 1.5).

By limiting the ratio of the sum of the light exit areas of the plurality of green light-emitting devices 22 to the sum of the light exit areas of the plurality of blue light-emitting devices 23, the ratio of attenuation in the luminance of the green light-emitting devices 22 in the display panel 100 over time may match to the ratio of attenuation in the luminance of the blue light-emitting devices 23 over time, thereby ameliorating the color shift phenomenon of the display panel 100 to improve the stability of the display performance and display effect of the display panel 100 on the basis of ensuring that the color gamut of the display panel 100 100% covers the NTSC color gamut standard.

In some embodiments, the ratio of the sum of the light exit areas of the plurality of green light-emitting devices 22 to the area of the display region of the display panel 100 is greater than the ratio of the sum of the light exit areas of the plurality of red light-emitting devices 21 to the area of the display region of the display panel 100. The ratio of the sum of the light exit areas of the plurality of blue light-emitting devices 23 to the area of the display region of the display panel 100 is also greater than the ratio of the sum of the light exit areas of the plurality of red light-emitting devices 21 to the area of the display region of the display panel 100.

The luminous efficiency of the red light-emitting devices 21 is greater than the luminous efficiency of the green light-emitting devices 22 and greater than the luminous efficiency of the blue light-emitting devices 23. Thus, by limiting that, in the display region of the display panel 100, the proportion of the sum of the light exit areas of the plurality of green light-emitting devices 22 is greater than the proportion of the sum of the light exit areas of the plurality of red light-emitting devices 21, and the proportion of the sum of the light exit areas of the plurality of blue light-emitting devices 23 is greater than the proportion of the sum of the light exit areas of the plurality of red light-emitting devices 21, in the same display panel 100, the ratio of attenuation in the luminance of the red light-emitting devices 21 over time, the ratio of attenuation in the luminance of the green light-emitting devices 22 over time, and the ratio of attenuation in the luminance of the blue light-emitting devices 23 over time are close to one another, thereby ensuring that the color gamut of the display panel 100 100% covers the NTSC color gamut standard, and ameliorating the color shift phenomenon of the display panel 100 to improve the stability of the display performance and display effect of the display panel 100.

In some embodiments, a ratio of the sum of the light exit areas of the plurality of blue light-emitting devices 23 to a sum of the light exit areas of the plurality of green light-emitting devices 22 and the light exit areas of the plurality of red light-emitting devices 21 is greater than or equal to 0.4 and less than or equal to 0.8 (e.g., 0.4, 0.5, 0.6, 0.7 or 0.8). It will be understood that a ratio of SB in the formula 1 to a sum of SG and SR in the formula 2 is greater than or equal to 0.4 and less than or equal to 0.8.

By limiting the ratio of the sum of the light exit areas of the plurality of blue light-emitting devices 23 to the sum of the light exit areas of the plurality of green light-emitting devices 22 and the light exit areas of the plurality of red light-emitting devices 21, the luminous efficiency of the blue light-emitting devices 23 may be relatively improved. Thus, in the same display panel 100, both the ratio of attenuation in the luminance of the red light-emitting devices 21 over time and the ratio of attenuation in the luminance of the green light-emitting devices 22 over time match the ratio of attenuation in the luminance of the blue light-emitting devices 23 over time, thereby ensuring that the color gamut of the display panel 100 100% covers the NTSC color gamut standard, and ameliorating the color shift phenomenon of the display panel 100 to improve the stability of the display performance and display effect of the display panel 100.

In some embodiments, as shown in FIGS. 3 and 9A, the encapsulation layer 30 is located on a side of the second electrode CE away from the base substrate 10. The encapsulation layer 30 may be of a single-layer structure or a multi-layer composite structure. The encapsulation layer 30 is configured to block moisture and oxygen from into the light-emitting unit 20.

In some examples, the encapsulation layer 30 includes a first inorganic layer 31, an organic layer 32 and a second inorganic layer 33 that are stacked in sequence in the direction away from the base substrate 10.

For example, dimensions of the first inorganic layer 31 and the second inorganic layer 33 in the direction perpendicular to the base substrate 10 are each greater than or equal to 0.5 μm and less than or equal to 2.0 μm (e.g., 0.5 μm, 0.8 μm, 1.0 μm, 1.2 μm, 1.5 μm, 1.7 μm or 2.0 μm). For another example, the dimension of the first inorganic layer 31 in the direction perpendicular to the base substrate 10 is 1.0 μm, and the dimension of the second inorganic layer 33 in the direction perpendicular to the t base substrate 10 is 0.7 μm.

For example, the materials of the first inorganic layer 31 and the second inorganic layer 33 are selected from at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride or lithium fluoride. The material of the organic layer 32 is at least one of acrylic resin, methacrylic resin, polyisoprene, vinyl resin, epoxy resin, polyurethane resin, cellulose resin or perylene resin. The number of layers, material and structure of the encapsulation layer 30 may be changed by those skilled in the art according to requirements, which is not limited in the present disclosure.

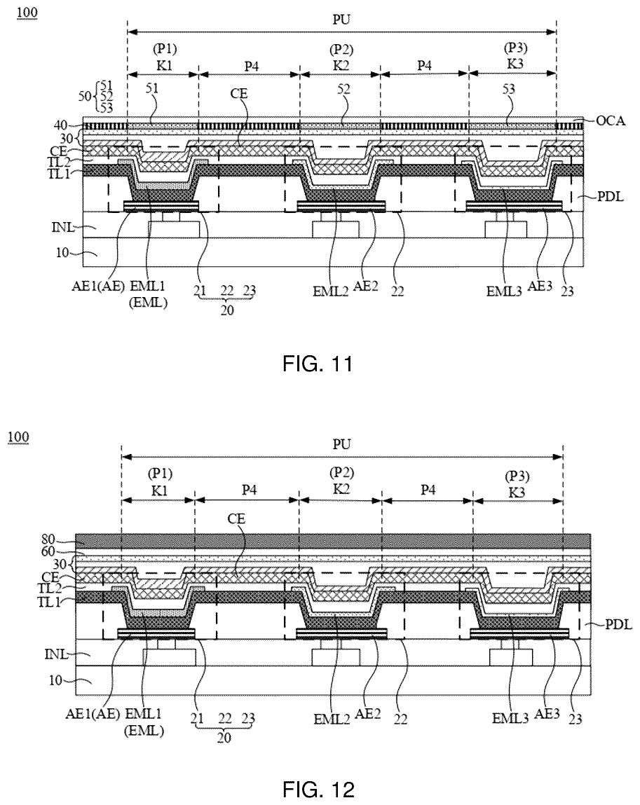

FIGS. 11 and 12 are each a structural diagram of the display panel, in accordance with some embodiments.

In some embodiments, as shown in FIGS. 9A and 11, the display panel 100 further includes photoresist blocks 40. The photoresist blocks 40 may be located on a side of the encapsulation layer 30 away from the base substrate 10, and the photoresist blocks 40 are located in the non-light-emitting region of the display panel 100. For example, the photoresist blocks 40 may be located on a side of the second inorganic layer away from the base substrate 10. For example, the photoresist blocks 40 may be made of a material of a black matrix.

As shown in FIG. 9A, a part of the display panel 100 in the light-emitting region that is in the same layer as the photoresist blocks 40 may be filled with the optically clear adhesive (OCA) to form a flat surface, which facilitates the manufacturing of components in subsequent processes.

The photoresist blocks 40 is configured to prevent light of different colors emitted from other light-emitting regions from entering the light-emitting region to ensure the color purity of the light emitted from each light-emitting region, which improves the contrast of the colors of the light emitted from all the light-emitting regions, thereby improving the display effect of the display panel 100.

In some embodiments, as shown in FIG. 11, the display panel 100 further includes a color filter film 50. The color filter film 50 may be arranged in the same layer as the photoresist blocks 40, and the color filter film 50 is located in the light-emitting regions of the display panel 100. It will be understood that the photoresist blocks 40 and the color filter film 50 are both formed on the surface of the encapsulation layer 30 away from the base substrate 10.

The dimensions of the photoresist block 40 and the color filter film 50 in the direction perpendicular to the base substrate 10 may be different. The photoresist blocks 40 and the color filter film 50 are coated with OCA to form a flat surface to facilitate the manufacturing of components in subsequent processes.

Due to the provision of the color filter film 50, it is possible to reduce the reflection of the light emitted by the light-emitting devices to filter out the noise in the light, which improves the light extraction efficiency of the display panel 100 and the saturation of the light, thereby improving the display effect of the display apparatus 1000.

In some examples, as shown in FIG. 11, the color filter film 50 includes at least one of a first filter film section 51, a second filter film section 52, or a third filter film section 53. For example, the color filter film 50 includes a first filter film segment 51, a second filter film segment 52 and a third filter film segment 53. The first filter film section 51 covers the first sub-pixel region P1, the second filter film section 52 covers the second sub-pixel region P2, and the third filter film section 53 covers the third sub-pixel region P3.

The first filter film segment 51 may transmit red light. The wavelength of the transmitted light of the first filter film section 51 is greater than or equal to 650 nm and less than or equal to 720 nm (e.g., 650 nm, 680 nm, 700 nm or 720 nm).

The second filter film section 52 may transmit green light. The wavelength of the transmitted light of the second filter film segment 52 is greater than or equal to 500 nm and less than or equal to 600 nm (e.g., 500 nm, 540 nm, 580 nm or 600 nm).

The third filter film section 53 may transmit blue light. The wavelength of the transmitted light of the third filter film segment 53 is greater than or equal to 430 nm and less than or equal to 480 nm (e.g., 430 nm, 450 nm, 460 nm or 480 nm).

In some examples, the ratio of the transmission spectrum of the color filter film 50 overlapping with the emission spectrum of the corresponding light-emitting device is greater than or equal to 80% (e.g., 80%, 82%, 85%, 90%, or 95%). The greater the ratio of the transmission spectrum of the color filter film 50 overlapping with the emission spectrum of the corresponding light-emitting device, the greater the amount of light emitted by the light-emitting device passes through the color filter film 50.

In some embodiments, as shown in FIGS. 9A and 12, the display panel 100 further includes an optical functional film 60. The optical functional layer 60 is located on a side of the encapsulation layer 30 away from the base substrate 10, and the optical functional layer 60 is configured to refract the light emitted by the light-emitting devices to enable the light to be converted into polarized light. For example, the optically functional layer 60 may be a quarter wave plate.

The optical functional layer 60 may change the propagation direction of light emitted from the light-emitting device to improve the light extraction efficiency of the display panel 100.

In some embodiments, as shown in FIG. 9A, the display panel 100 further includes a light gain layer 70. The light gain layer 70 may be located between the light-emitting unit 20 and the optical functional layer 60, and includes at least one of a red light gain layer, a green light gain layer, and a blue light gain layer that are sequentially stacked in the direction perpendicular to the base substrate 10. The light gain layer 70 may improve the luminance and luminous efficiency of the display panel 100, ameliorate the color shift phenomenon of the display panel 100, and improve the display effect of the display apparatus 1000.

The red light gain layer may transmit red light with a wavelength greater than or equal to 650 nm and less than or equal to 720 nm (e.g., 650 nm, 680 nm, 700 nm or 720 nm). The green light gain layer may transmit green light with a wavelength greater than or equal to 500 nm and less than or equal to 600 nm (e.g. 500 nm, 540 nm, 580 nm or 600 nm). The blue light gain layer may transmit blue light with a wavelength greater than or equal to 430 nm and less than or equal to 480 nm (e.g., 430 nm, 450 nm, 460 nm or 480 nm).

For example, the dimensions of the red light gain layer, the green light gain layer and the blue light gain layer in the direction perpendicular to the base substrate 10 are each greater than or equal to 4 μm and less than or equal to 6 μm (e.g., 4 μm, 4.5 μm, 5 μm or 6 μm). The adjacent red light gain layer, green light gain layer and blue light gain layer may be bonded to each other by OCA.

For example, the light gain layer 70 may be a circularly polarized light gain layer 70. The reflectivity of the light gain layer 70 is greater than or equal to 45% (e.g., 45%, 50%, 60%, 65%, or 70%). In addition to red light, green light and blue light, and the transmittance of light with the wavelength greater than or equal to 400 nm and less than or equal to 800 nm (e.g., 400 nm, 500 nm, 600 nm, 700 nm or 800 nm) through the circular polarizer is greater than or equal to 95% (e.g., 95%, 96%, 97% or 98%).

In some examples, the light gain layer 70 includes a green light gain layer and a blue light gain layer sequentially stacked in the direction perpendicular to the base substrate 10.

Due to the provision of the green light gain layer and the blue light gain layer, the luminance of the green light-emitting devices 22 and the blue light-emitting devices 23 in the same display panel 100 may be improved, so that both the ratio of attenuation in the luminance of the green light-emitting devices 22 and the ratio of attenuation in the luminance of the blue light-emitting devices 23 are close to the ratio of attenuation in the luminance of the red light-emitting devices 21, thereby ameliorating the color shift phenomenon of the display panel 100 and improving the display effect of the display apparatus 1000.

In some embodiments, as shown in FIGS. 9A and 12, the display panel 100 further includes an anti-reflective layer 80. The anti-reflective layer 80 is located on a side of the light-emitting unit 20 away from the base substrate 10 and is configured to deflect light emitted from the light-emitting device towards the direction perpendicular to the base substrate 10.

In some examples, as shown in FIG. 12, the anti-reflective layer 80 may be located on a surface of the optical functional layer 60 away from the encapsulation layer 30. The light emitted from the light-emitting device first passes through the optical functional layer 60 to become polarized light, and then the polarized light enters the anti-reflection layer 80. Thus, it may be possible to deflect the light emitted from the light-emitting device towards the direction perpendicular to the base substrate 10 to reduce the reflection of light emitted from the light-emitting device, which may improve the contrast of the light of the display panel 100, thereby improving the display effect of the display apparatus 1000.

In some examples, as shown in FIG. 9A, the anti-reflective layer 80 may be located on a surface of the optical functional layer 60 away from the light gain layer 70. The light emitted from the light-emitting device first passes through the optical gain layer 70 to increase the luminance, and then passes through the optical functional layer 60 to become polarized light, and the polarized light then enters the anti-reflection layer 80, which may reduce the reflection of the light emitted from the light-emitting device to improve the contrast and the luminance of the light of the display panel 100, thereby improving the display effect of the display apparatus 1000.

As shown in FIG. 12, the display panel 100 includes the base substrate 10, the light-emitting unit 20, the encapsulation layer 30, the optical functional layer 60 and the anti-reflective layer 80. The light-emitting unit 20 is located on a side of the base substrate 10, the encapsulation layer 30 is located on the surface of the light-emitting unit 20 away from the base substrate 10, the optical functional layer 60 is located on the surface of the encapsulation layer 30 away from the light-emitting unit 20, and the anti-reflective layer 80 is located on the surface of the optical functional layer 60 away from the encapsulation layer 30. Experimental devices 1, 2, and 3 and Comparative devices 1, 2, and 3, whose macrostructures are each substantially the same as that of the display panel 100 shown in FIG. 12 are manufactured, and the specific performance parameters of Experimental devices 1, 2 and 3, and Comparative devices 1, 2 and 3 are as shown in Table 1 below.

TABLE 1

| | E_{R} | E_{G} | RO_{R} | RO_{G} | CIE-R | CIE-G | CIE-B |
|---|---|---|---|---|---|---|---|
| Experimental | 70.4 | 161.3 | 0.06 | 0.14 | 0.67, | 0.21, | 0.14, |
| device 1 | | | | | 0.33 | 0.71 | 0.08 |
| Experimental | 71.1 | 162.8 | 0.06 | 0.15 | | | |
| device 2 | | | | | | | |
| Experimental | 69.8 | 157.3 | 0.04 | 0.14 | | | |
| device 3 | | | | | | | |
| Comparative | 70.6 | 161.1 | 0.07 | 0.14 | | | |
| device 1 | | | | | | | |
| Comparative | 70.8 | 160.8 | 0.05 | 0.14 | | | |
| device 2 | | | | | | | |
| Comparative | 71.5 | 159.7 | 0.06 | 0.13 | | | |
| device 3 | | | | | | | |

The main difference between Experimental device 1, Experimental device 2, Experimental device 3, Comparative device 1, Comparative device 2 and Comparative device 3 is that the ratio SR of the sum of the light exit areas of the plurality of red light-emitting devices 21 to the area of the display region of the display panel 100, the ratio SG of the sum of the light exit areas of the plurality of green light-emitting devices 22 to the area of the display region of the display panel 100, and the ratio SB of the sum of the light exit areas of the plurality of blue light-emitting devices 23 to the area of the display region of the display panel 100 are different.

Based on the data in Table 1 and a case that the value of f of the display panel 100 as shown in FIG. 12 is 0.43, the respective parameters SR, SG, and SB of Experimental device 1, Experimental device 2, Experimental device 3, Comparative device 1, Comparative device 2, and Comparative device 3 are obtained by the formula 1 and the formula 2, and as shown in Table 2 below.

TABLE 2

| | | | | | Des. SG/SR | | | Des. SB | |
|---|---|---|---|---|---|---|---|---|---|
| | SR | SG | SB | SG/SR | @Formula 2 | L | JB | @Formula 1 | LR:LG:LB |
| Experimental | 5% | 10% | 8.5% | 2 | ≥1.35 | 535 | 61 | ≥6.9% | 983:992:976 |
| device 1 | | | | | and ≤2.17 | | | | |
| Experimental | 6% | 9% | 8.5% | 1.5 | ≥1.37 | 541 | 64 | ≥6.2% | 987:990:976 |
| device 2 | | | | | and ≤2.19 | | | | |
| Experimental | 4.5% | 9% | 10% | 2 | ≥1.40 | 622 | 63 | ≥7.3% | 983:991:980 |
| device 3 | | | | | and ≤2.25 | | | | |
| Comparative | 6.2% | 12.3% | 5% | 1.98 | ≥1.34 | 450 | 56 | ≥5.7% | 991:998:896 |
| device 1 | | | | | and ≤2.15 | | | | |
| Comparative | 3% | 12% | 8.5% | 4 | ≥1.38 | 523 | 63 | ≥6.1% | 957:997:965 |
| device 2 | | | | | and ≤2.21 | | | | |
| Comparative | 12.3% | 6.2% | 5% | 0.50 | ≥1.37 | 436 | 60 | ≥5.3% | 999:954:872 |
| device 3 | | | | | and ≤2.20 | | | | |

In Table 2, Des. SG/SR @Formula 2 represents the value range of SG/SR calculated according to the formula 2; Des.SB@Formula 1 represents the value range of SB calculated according to the formula 1; LR, LG, LB are respectively the permillage of the remaining luminance to the initial luminance after the aging experiment of the red light-emitting devices 21, the green light-emitting devices 22 and the blue light-emitting devices 23 in the same display panel 100, i.e., the permillage LR of the remaining luminance to the initial luminance of the red light-emitting devices 21, the permillage LG of the remaining luminance to the initial luminance of the green light-emitting devices 22, and the permillage LB of the remaining luminance to the initial luminance of the blue light-emitting devices 23 after the display panel 100 is continuously lit up for 200 h under the operating condition in which the chromaticity coordinate value CIE of the white light is (0.31, 0.32) and the luminance of the white light is 800 cd/m²; LR:LG:LB represents a ratio of the permillage of the remaining luminance to the initial luminance of the red light-emitting devices 21 to the permillage of the remaining luminance to the initial luminance of the green light-emitting devices 22 to the permillage of the remaining luminance to the initial luminance of the blue light-emitting devices 23.

Based on the data in Table 1 and the data in Table 2, it can be seen that, for Experimental devices 1 to 3 and Comparative devices 1 to 3, the ratio of the sum of the light exit areas of all the red light-emitting devices 21 to the area of the display region of the display panel 100, the ratio of the sum of the light exit areas of all the green light-emitting devices 22 to the area of the display region of the display panel 100, and the ratio of the sum of the light exit areas of all the blue light-emitting devices to the area of the display region of the display panel 100 are the same, and the initial chromaticity coordinate values of white light are the same; the main differences between Experimental devices 1 to 3 and Comparative devices 1 to 3 are that, Experimental device 1, Experimental device 2 and Experimental device 3 all satisfy the value range of SB calculated by the formula 1 and the value range of SG/SR calculated by the formula 2, Comparative device 1 satisfies the value range of SG/SR calculated by the formula 2 but does not satisfy the value range of SB calculated by the formula 1, Comparative device 2 satisfies the value range of SB calculated by the formula 1 but does not satisfy the value range of SG/SR calculated by the formula 2, and Comparative device 3 neither satisfies the value range of SB calculated by the formula 1 nor does it satisfy the value range of SG/SR calculated by the formula 2.

Referring to and comparing the parameters LR:LG:LB in Table 2, it can be seen that, for Experimental device 1, Experimental device 2 and Experimental device 3, the ratio of attenuation in the luminance of the red light-emitting devices 21 over time, the ratio of attenuation in the luminance of the green light-emitting devices 22 over time, and the ratio of attenuation in the luminance of the blue light-emitting devices 23 over time are close to one another, and no obvious chromaticity coordinate shift phenomenon of white light occurs in Experimental device 1, Experimental device 2 and Experimental device 3; the ratio of attenuation in the luminance of the blue light-emitting devices 23 in Comparative device 1 over time is too great, the ratio of attenuation in the luminance of the red light-emitting devices 21 in Comparative device 2 over time is too great, and the ratio of attenuation in the luminance of the green light-emitting devices 22 in Comparative device 3 over time is too great; and obvious chromaticity coordinate shift phenomenon of white light occurs in Comparative device 1, Comparative device 2 and Comparative device 3. It will be understood that, SB is calculated through the formula 1, which may reduce the ratio of attenuation in the luminance of the blue light-emitting devices 23 over time; SG/SR is calculated through the formula 2, so that the ratio of attenuation in the luminance of the red light-emitting devices 21 over time is close to the ratio of attenuation in the luminance of the green light-emitting devices 22 over time. Moreover, by setting the operating conditions of the same chromaticity coordinates of the white light emitted by the display panel 100, in the same display panel 100, the ratio of attenuation in the luminance of the red light-emitting devices 21 over time, the ratio of attenuation in the luminance of the green light-emitting devices 22 over time, and the ratio of attenuation in the luminance of the blue light-emitting devices 23 over time are close to one another, thereby ameliorating the color shift phenomenon of the display panel 100 to improve the stability of the display performance and the display effect of the display panel 100.

As shown in FIG. 9A, the display panel 100 includes the base substrate 10, the light-emitting unit 20, the encapsulation layer 30, the light gain layer 70, the optical functional layer 60 and the anti-reflective layer 80. The light-emitting unit 20 is located on a side of the base substrate 10, the encapsulation layer 30 is located on the surface of the light-emitting unit 20 away from the base substrate 10, the light gain layer 70 is located on the surface of the encapsulation layer 30 away from the light-emitting unit 20, and the optical functional layer 60 is located on the surface of the light gain layer 70 away from the encapsulation layer 30, and the anti-reflection layer 80 is located on the surface of the optical functional layer 60 away from the light gain layer 70. Experimental devices 4, 5, and 6 and Comparative devices 4, 5, and 6, whose macrostructures are each substantially the same as that of the display panel 100 shown in FIG. 9A are manufactured, and the specific performance parameters of Experimental devices 4, 5 and 6, and Comparative devices 4, 5 and 6 are as shown in Table 1 below.

TABLE 3

| | E_{R} | E_{G} | RO_{R} | RO_{G} | CIE-R | CIE-G | CIE-B |
|---|---|---|---|---|---|---|---|
| Experimental | 97.9 | 200 | 0.06 | 0.14 | 0.67, | 0.21, | 0.14, |
| device 4 | | | | | 0.33 | 0.71 | 0.08 |
| Experimental | 98.8 | 201.9 | 0.06 | 0.15 | | | |
| device 5 | | | | | | | |
| Experimental | 97 | 195.1 | 0.04 | 0.14 | | | |
| device 6 | | | | | | | |
| Comparative | 98.1 | 199.8 | 0.07 | 0.14 | | | |
| device 4 | | | | | | | |
| Comparative | 98.4 | 199.4 | 0.05 | 0.14 | | | |
| device 5 | | | | | | | |
| Comparative | 99.4 | 198 | 0.06 | 0.13 | | | |
| device 6 | | | | | | | |

The main difference between Experimental device 4, Experimental device 5, Experimental device 6, Comparative device 4, Comparative device 5 and Comparative device 6 is that the ratio SR of the sum of the light exit areas of the plurality of red light-emitting devices 21 to the area of the display region of the display panel 100, the ratio SG of the sum of the light exit areas of the plurality of green light-emitting devices 22 to the area of the display region of the display panel 100, and the ratio SB of the sum of the light exit areas of the plurality of blue light-emitting devices 23 to the area of the display region of the display panel 100 are different.

Based on the data in Table 3 and a case that the value of f of the display panel 100 as shown in FIG. 9A is 0.7, the respective parameters SR, SG, and SB of Experimental device 4, Experimental device 5, Experimental device 6, Comparative device 4, Comparative device 5, and Comparative device 6 are obtained by the formula 1 and the formula 2, and as shown in Table 4 below.

TABLE 4

| | | | | | Des. SG/SR | | | Des. SB | |
|---|---|---|---|---|---|---|---|---|---|
| | SR | SG | SB | SG/SR | @Formula 2 | L | JB | @Formula 1 | LR:LG:LB |
| Experimental | 5% | 10% | 8.5% | 2 | ≥1.51 | 738 | 62 | ≥5.4% | 996:998:990 |
| device 4 | | | | | and ≤2.43 | | | | |
| Experimental | 5.4% | 9.6% | 8.5% | 1.78 | ≥1.53 | 747 | 64 | ≥5.3% | 995:997:991 |
| device 5 | | | | | and ≤2.46 | | | | |
| Experimental | 4.5% | 9% | 10% | 2 | ≥1.57 | 858 | 63 | ≥6.2% | 997:999:995 |
| device 6 | | | | | and ≤2.52 | | | | |
| Comparative | 6.2% | 12.4% | 5% | 1.98 | ≥1.50 | 621 | 53 | ≥5.1% | 996:998:976 |
| device 4 | | | | | and ≤2.41 | | | | |
| Comparative | 3% | 12% | 8.5% | 4 | ≥1.54 | 722 | 63 | ≥5.2% | 990:999:982 |
| device 5 | | | | | and ≤2.48 | | | | |
| Comparative | 12.3% | 6.2% | 5% | 0.50 | ≥1.54 | 602 | 62 | ≥4.5% | 1000:992:978 |
| device 6 | | | | | and ≤2.46 | | | | |

Based on the data in Table 3 and the data in Table 4, it can be seen that, for Experimental devices 4 to 6 and Comparative devices 4 to 6, the ratio of the sum of the light exit areas of all the red light-emitting devices 21 to the area of the display region of the display panel 100, the ratio of the sum of the light exit areas of all the green light-emitting devices 22 to the area of the display region of the display panel 100, and the ratio of the sum of the light exit areas of all the blue light-emitting devices to the area of the display region of the display panel 100 are the same, and the initial chromaticity coordinate values of white light are the same; the main difference between Experimental devices 4 to 6 and Comparative devices 4 to 6 is that, Experimental device 4, Experimental device 5 and Experimental device 6 all satisfy the value range of SB calculated by the formula 1 and the value range of SG/SR calculated by the formula 2, Comparative device 4 satisfies the value range of SG/SR calculated by the formula 2 but does not satisfy the value range of SB calculated by the formula 1, Comparative device 5 satisfies the value range of SB calculated by the formula 1 but does not satisfy the value range of SG/SR calculated by the formula 2, and Comparative device 6 does not satisfy the value range of SG/SR calculated by the formula 2 but satisfies the value range of SB calculated by the formula 1.

Referring to and comparing the parameters LR:LG:LB in Table 4, it can be seen that, for Experimental device 4, Experimental device 5 and Experimental device 6, the ratio of attenuation in the luminance of the red light-emitting devices 21 over time, the ratio of attenuation in the luminance of the green light-emitting devices 22 over time, and the ratio of attenuation in the luminance of the blue light-emitting devices 23 over time are close to one another, and no obvious chromaticity coordinate shift phenomenon of white light occurs in Experimental device 4, Experimental device 5 and Experimental device 6; for Comparative device 4, Comparative device 5 and Comparative device 6, the ratio of attenuation in the luminance of the blue light-emitting devices 23 over time is significantly greater than the ratio of attenuation in the luminance of the red light-emitting devices 21 over time, and the ratio of attenuation in the luminance of the blue light-emitting devices 23 over time is also significantly greater than the ratio of attenuation in the luminance of the green light-emitting devices 22 over time; and obvious chromaticity coordinate shift phenomenon of white light occurs in Comparative device 4, Comparative device 5 and Comparative device 6.

The main difference between Experimental devices 4 to 6 and Experimental devices 1 to 3 is that Experimental devices 4 to 6 each include the optical gain layer 70 and the optical functional layer 60. Referring to and comparing the parameters LR:LG:LB in Table 2 and the parameters LR:LG:LB in Table 4, it can be seen that, comparing Experimental devices 4 to 6 with Experimental devices 1 to 3, the ratio of attenuation in the luminance of the red light-emitting devices 21 over time, the ratio of attenuation in the luminance of the green light-emitting devices 22 over time, and the ratio of attenuation in the luminance of the blue light-emitting devices 23 over time are more closer to one another, and the luminance and luminous efficiency of each light-emitting device are higher. It will be understood that, due to the provision of the light gain layer 70 and the optical functional layer 60, it may be possible to improve the luminance and luminous efficiency of the display panel 100, and ameliorate the color shift phenomenon of the display panel 100, thereby improving the display effect of the display apparatus 1000.

As shown in FIG. 11, the display panel 100 includes the base substrate 10, the light-emitting unit 20, the encapsulation layer 30, the photoresist blocks 40 and the color filter film 50. The light-emitting unit 20 is located on a side of the base substrate 10, the encapsulation layer 30 is located on the surface of the light-emitting unit 20 away from the base substrate 10, the photoresist blocks 40 and the color filter film 50 are arranged in the same layer and located on the surface of the encapsulation layer 30 away from the light-emitting unit 20. Experimental devices 7, 8, and 9 and Comparative devices 7, 8, and 9, whose macrostructures are each substantially the same as that of the display panel 100 shown in FIG. 11 are manufactured, and the specific performance parameters of Experimental devices 7, 8 and 9, and Comparative devices 7, 8 and 9 are as shown in Table 5 below.

TABLE 5

| | E_{R} | E_{G} | RO_{R} | RO_{G} | CIE-R | CIE-G | CIE-B |
|---|---|---|---|---|---|---|---|
| Experimental | 84.5 | 204.9 | 0.06 | 0.14 | 0.67, | 0.21, | 0.14, |
| device 7 | | | | | 0.33 | 0.71 | 0.08 |
| Experimental | 85.3 | 206.8 | 0.06 | 0.15 | | | |
| device 8 | | | | | | | |
| Experimental | 83.8 | 199.8 | 0.04 | 0.14 | | | |
| device 9 | | | | | | | |
| Comparative | 84.7 | 204.6 | 0.07 | 0.14 | | | |
| device 7 | | | | | | | |
| Comparative | 85.0 | 204.2 | 0.05 | 0.14 | | | |
| device 8 | | | | | | | |
| Comparative | 85.8 | 202.8 | 0.06 | 0.13 | | | |
| device 9 | | | | | | | |

The main difference between Experimental device 7, Experimental device 8, Experimental device 9, Comparative device 7, Comparative device 8 and Comparative device 9 is that the ratio SR of the sum of the light exit areas of the plurality of red light-emitting devices 21 to the area of the display region of the display panel 100, the ratio SG of the sum of the light exit areas of the plurality of green light-emitting devices 22 to the area of the display region of the display panel 100, and the ratio SB of the sum of the light exit areas of the plurality of blue light-emitting devices 23 to the area of the display region of the display panel 100 are different.

Based on the data in Table 5 and a case that the value of f in the display panel 100 shown in FIG. 11 is 0.8, the respective parameters SR, SG, and SB of Experimental device 7, Experimental device 8, Experimental device 9, Comparative device 7, Comparative device 8, and Comparative device 9 are obtained by the formula 1 and formula 2, and as shown in Table 6 below.

TABLE 6

| | | | | | Des. SG/SR | | | Des. SB | |
|---|---|---|---|---|---|---|---|---|---|
| | SR | SG | SB | SG/SR | @Formula 1 | L | JB | @Formula 2 | LR:LG:LB |
| Experimental | 5% | 10% | 8.5% | 2 | ≥1.28 | 696 | 59 | ≥4.6% | 993:994:989 |
| device 7 | | | | | and ≤2.05 | | | | |
| Experimental | 6% | 9% | 8.5% | 1.5 | ≥1.29 | 703 | 66 | ≥4.3% | 994:994:988 |
| device 8 | | | | | and ≤2.07 | | | | |
| Experimental | 4.5% | 9% | 10% | 2 | ≥1.33 | 809 | 62 | ≥5.1% | 988:992:992 |
| device 9 | | | | | and ≤2.13 | | | | |
| Comparative | 7.2% | 14.3% | 2% | 1.99 | ≥1.27 | 585 | 60 | ≥3.8% | 993:996:931 |
| device 7 | | | | | and ≤2.03 | | | | |
| Comparative | 3% | 12% | 8.5% | 4 | ≥1.30 | 680 | 63 | ≥4.3% | 989:999:986 |
| device 8 | | | | | and ≤2.09 | | | | |
| Comparative | 12.3% | 6.2% | 5% | 0.50 | ≥1.29 | 567 | 59 | ≥3.7% | 999:981:956 |
| device 9 | | | | | and ≤2.08 | | | | |

Based on the data in Table 5 and the data in Table 6, it can be seen that, for Experimental devices 7 to 9 and Comparative devices 7 to 9, the ratio of the sum of the light exit areas of all the red light-emitting devices 21 to the area of the display region of the display panel 100, the ratio of the sum of the light exit areas of all the green light-emitting devices 22 to the area of the display region of the display panel 100, and the ratio of the sum of the light exit areas of all the blue light-emitting devices 23 to the area of the display region of the display panel 100 are the same, and the initial chromaticity coordinate values of white light are the same; the main differences between Experimental devices 7 to 9 and Comparative devices 7 to 9 are that, Experimental device 7, Experimental device 8 and Experimental device 9 all satisfy the value range of SB calculated by the formula 1 and the value range of SG/SR calculated by the formula 2, Comparative device 7 satisfies the value range of SG/SR calculated by the formula 2 but does not satisfy the value range of SB calculated by the formula 1, Comparative device 8 satisfies the value range of SB calculated by the formula 1 but does not satisfy the value range of SG/SR calculated by the formula 2, and Comparative device 9 satisfies the value range of SB calculated by the formula 1 but does not satisfy the value range of SG/SR calculated by the formula 2.

Referring to and comparing the parameters LR:LG:LB in Table 6, it can be seen that, for Experimental device 7, Experimental device 8 and Experimental device 9, the ratio of attenuation in the luminance of the red light-emitting devices 21 over time, the ratio of attenuation in the luminance of the green light-emitting devices 22 over time, and the ratio of attenuation in the luminance of the blue light-emitting devices 23 over time are close to one another, and no obvious chromaticity coordinate shift phenomenon of white light occurs in Experimental device 7, Experimental device 8 and Experimental device 9; for Comparative device 7, the ratio of attenuation in the luminance of the blue light-emitting devices 23 over time is great; for Comparative device 8, the ratio of attenuation in the luminance of the red light-emitting devices 21 over time is greater than the ratio of attenuation in the luminance of the green light-emitting devices 22 over time, and the ratio of attenuation in the luminance of the blue light-emitting devices 23 over time is also greater than the ratio of attenuation in the luminance of the green light-emitting devices 22 over time; for Comparative device 9, the ratio of attenuation in the luminance of the blue light-emitting devices 23 over time is great; moreover, obvious chromaticity coordinate shift phenomenon of white light occurs in both Comparative device 7 and Comparative device 9. It will be understood that, in the same display panel 100, both the ratio of attenuation in the luminance of the red light-emitting devices 21 over time and the ratio of attenuation in the luminance of the green light-emitting devices 22 over time may match the ratio of attenuation in the luminance of the blue light-emitting devices 23 over time, which may ameliorate the color shift phenomenon of the display panel 100 to improve the stability of the display performance and the display effect of the display panel 100.

To sum up, in the display panel 100 and the display apparatus 1000 provided by the embodiments of the present disclosure, the ratio of the sum of the light exit areas of the plurality of blue light-emitting devices 23 to the area of the display region of the display panel 100 is limited to an appropriate range, which may increase the effective light-emitting areas of the plurality of blue light-emitting devices 23 in the display panel 100, thereby improving the luminous efficiency of the blue light-emitting devices 23 and the display brightness of blue light in the display panel 100. As a result, the ratio of attenuation in the luminance of the blue light-emitting devices 23 in the display panel 100 over time is reduced, thereby ameliorating the color shift phenomenon of the display panel 100 to improve the display effect of the display apparatus 1000.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel comprising a display region and a non-display region, wherein the display panel comprises:
a base substrate; and
a light-emitting unit located on a side of the base substrate, the light-emitting unit including a plurality of light-emitting devices, the plurality of light-emitting devices including a plurality of red light-emitting devices, a plurality of green light-emitting devices and a plurality of blue light-emitting devices;
wherein a ratio of a sum of light exit areas of the plurality of blue light-emitting devices to an area of the display region of the display panel is greater than or equal to 4% and less than or equal to 25%.

2. The display panel according to claim 1, wherein the ratio of the sum of the light exit areas of the plurality of blue light-emitting devices to the area of the display region of the display panel is greater than or equal to 5% and less than or equal to 18%.

3. The display panel according to claim 1, wherein the ratio of the sum of the light exit areas of the plurality of blue light-emitting devices to the area of the display region of the display panel satisfies a following formula 1:
$$\frac{0.15 L}{{J}_{B} [ 50 - {RO}_{B} ( {J}_{B} - 50 ) ] f} \leq SB ;$$
in the formula 1, SB represents the ratio of the sum of the light exit areas of the plurality of blue light-emitting devices to the area of the display region of the display panel; L represents a maximum operating luminance of the blue light-emitting devices under a first operating condition; J_{B} represents a current density of the blue light-emitting devices under the first operating condition; RO_{B} represents a ratio of decrease in a current efficiency of the blue light-emitting devices in a case where the current density of the blue light-emitting devices is increased from 5 mA/cm² to 10 mA/cm²; f represents a maximum value of an external quantum efficiency of the blue light-emitting devices that is defined as a maximum value of a ratio of a number of photons radiated by the blue light-emitting devices to a number of hole-electron pairs recombined in the blue light-emitting devices; wherein
the first operating condition is an operating condition in which, for chromaticity coordinates of white light emitted by the display panel, an abscissa value is greater than or equal to 0.30 and less than or equal to 0.33 and an ordinate value is greater than or equal to 0.31 and less than or equal to 0.34, and a service life of the blue light-emitting devices is greater than or equal to 300 h.

4. The display panel according to claim 1, wherein a ratio of a sum of light exit areas of the plurality of green light-emitting devices to a sum of light exit areas of the plurality of red light-emitting devices is greater than 1 and less than or equal to 4; or
the ration of the sum of light exit areas of the plurality of green light-emitting devices to the sum of light exit areas of the plurality of red light-emitting devices is greater than 1 and less than or equal to 3.

5. (canceled)

6. The display panel according to claim 1, wherein a ratio of a sum of light exit areas of the plurality of green light-emitting devices to a sum of light exit areas of the plurality of red light-emitting devices satisfies a following formula 2:
$$\frac{2.833 {E}_{R} ( 1 - {RO}_{R} )}{{E}_{G} ( 1 - {RO}_{G} )} \leq \frac{SG}{SR} \leq \frac{3.043 {E}_{R} ( 1 - {RO}_{R} )}{{E}_{G} ( 1 - {RO}_{G} ) {k}_{lim}} ;$$
in the formula 2, SG represents a ratio of the sum of the light exit areas of the plurality of green light-emitting devices to the area of the display region of the display panel; SR represents a ratio of the sum of the light exit areas of the plurality of red light-emitting devices to the area of the display region of the display panel; E_{G} represents a current efficiency of the green light-emitting devices in a case where a current density of the green light-emitting devices is 10 mA/cm²; E_{R} represents a current efficiency of the red light-emitting devices in a case where a current density of the red light-emitting devices is 10 mA/cm²; RO_{G} represents a ratio of decrease in the current efficiency of the green light-emitting devices in a case where the current density of the green light-emitting devices is increased from 10 mA/cm² to 20 mA/cm²; RO_{R} represents a ratio of decrease in the current efficiency of the red light-emitting devices in a case where the current density of the red light-emitting devices is increased from 10 mA/cm² to 20 mA/cm²; kₗᵢₘ represents a maximum value of a ratio of an operating current of the green light-emitting devices to an operating current of the red light-emitting devices under a second operating condition; wherein
the second operating condition is an operating condition in which an operating luminance of the display panel is greater than or equal to 100 nit and less than or equal to 800 nit, and for chromaticity coordinates of white light emitted by the display panel, an abscissa value is greater than or equal to 0.30 and less than or equal to 0.33, and an ordinate value is greater than or equal to 0.31 and less than or equal to 0.34.

7. The display panel according to claim 1, wherein a blue light-emitting device includes at least one blue light-emitting layer, and a light-emitting material of the blue light-emitting layer includes a metal complex; and
the metal complex includes at least one of metal ligand elements of platinum, palladium, iridium, gold, nickel, silver, copper or cerium.

8. The display panel according to claim 1, further comprising:
a pixel definition layer located on the base substrate and provided with a plurality of light-emitting openings therein; wherein the plurality of light-emitting openings include a plurality of first light-emitting openings, a plurality of second light-emitting openings and a plurality of third light-emitting openings, a red light-emitting device covers a first light-emitting opening, a green light-emitting device covers a second light-emitting opening, and a blue light-emitting device covers a third light-emitting opening; wherein
a ratio of a sum of areas of the plurality of first light-emitting openings to a sum of areas of the plurality of second light-emitting openings is substantially same as a ratio of a sum of light exit areas of the plurality of red light-emitting devices to a sum of light exit areas of the plurality of green light-emitting devices; and/or
a ratio of the sum of the areas of the plurality of first light-emitting openings to a sum of areas of the plurality of third light-emitting openings is substantially same as a ratio of the sum of the light exit areas of the plurality of red light-emitting devices to the sum of the light exit areas of the plurality of blue light-emitting devices; and/or
a ratio of the sum of the areas of the plurality of second light-emitting openings to the sum of the areas of the plurality of third light-emitting openings is substantially same as a ratio of the sum of the light exit areas of the plurality of green light-emitting devices to the sum of the light exit areas of the plurality of blue light-emitting devices.

9. The display panel according to claim 1, wherein a ratio of a sum of light exit areas of the plurality of green light-emitting devices to the area of the display region of the display panel is greater than a ratio of a sum of light exit areas of the plurality of red light-emitting devices to the area of the display region of the display panel; and
the ratio of the sum of the light exit areas of the plurality of blue light-emitting devices to the area of the display region of the display panel is greater than the ratio of the sum of the light exit areas of the plurality of red light-emitting devices to the area of the display region of the display panel.

10. The display panel according to claim 1, wherein a ratio of a sum of light exit areas of the plurality of red light-emitting devices to the sum of the light exit areas of the plurality of blue light-emitting devices is greater than or equal to 0.4 and less than or equal to 0.8.

11. The display panel according to claim 1, wherein a ratio of a sum of light exit areas of the plurality of green light-emitting devices to the sum of the light exit areas of the plurality of blue light-emitting devices is greater than or equal to 0.8 and less than or equal to 1.5.

12. The display panel according to claim 1, wherein a ratio of the sum of the light exit areas of the plurality of blue light-emitting devices to a sum of light exit areas of the plurality of green light-emitting devices and light exit areas of the plurality of red light-emitting devices is greater than or equal to 0.4 and less than or equal to 0.8.

13. The display panel according to claim 1, wherein the display region includes light-emitting regions of the plurality of light-emitting devices and a non-light-emitting region except for the light-emitting regions of the plurality of light-emitting devices; wherein
a ratio of the sum of the light exit areas of the plurality of blue light-emitting devices to an area of the non-light-emitting region is greater than or equal to 4% and less than or equal to 75%.

14. The display panel according to claim 13, further comprising:
a pixel definition layer located on the base substrate and provided with a plurality of light-emitting openings therein;
wherein a ratio of a sum of areas of the plurality of light-emitting openings to the area of the non-light-emitting region is greater than or equal to 0.2 and less than or equal to 2.0; and/or
a ratio of the sum of the areas of the plurality of light-emitting openings to the area of the display region of the display panel is greater than or equal to 0.15 and less than or equal to 0.65.

15. The display panel according to claim 1, further comprising:
an anti-reflection layer located on a side of the light-emitting unit away from the base substrate and configured to deflect light emitted by the light-emitting devices towards a direction perpendicular to the base substrate.

16. The display panel according to claim 15, further comprising:
an optical functional layer located between the light-emitting unit and the anti-reflection layer and configured to refract the light emitted by the light-emitting devices to enable the light to be converted into polarized light.

17. The display panel according to claim 16, further comprising:
a light gain layer located between the light-emitting unit and the optical functional layer and including at least one of a red light gain layer, a green light gain layer and a blue light gain layer that are sequentially stacked in the direction perpendicular to the base substrate.

18. A display panel comprising a display region and a non-display region, wherein the display panel comprises:
a base substrate;
a pixel definition layer located on the base substrate and provided with a plurality of first light-emitting openings, a plurality of second light-emitting openings and a plurality of third light-emitting openings therein; and
a light-emitting unit including a plurality of light-emitting devices, wherein the plurality of light-emitting devices include a plurality of first color light-emitting devices, a plurality of second color light-emitting devices and a plurality of third color light-emitting devices, a first color light-emitting device covers a first light-emitting opening, a second color light-emitting device covers a second light-emitting opening, and a third color light-emitting device covers a third light-emitting opening;
wherein a ratio of a sum of areas of the plurality of third light-emitting openings to an area of the display region of the display panel is greater than or equal to 4% and less than or equal to 25%; and/or
the ratio of the sum of the areas of the plurality of third light-emitting openings to the area of the display region of the display panel satisfies a following formula 1:
$$\frac{0.15 L}{{J}_{B} [ 50 - {RO}_{B} ( {J}_{B} - 50 ) ] f} \leq SB ;$$
in the formula 1, SB represents the ratio of the sum of the areas of the plurality of third light-emitting openings to the area of the display region of the display panel; L represents a maximum operating luminance of the third color light-emitting devices under a first operating condition; J_{B} represents a current density of the third color light-emitting devices under the first operating condition; RO_{B} represents a ratio of decrease in a current efficiency of the third color light-emitting devices in a case where the current density of the third color light-emitting devices is increased from 5 mA/cm² to 10 mA/cm²; f represents a maximum value of an external quantum efficiency of the third color light-emitting devices that is defined as a maximum value of a ratio of a number of photons radiated by the third color light-emitting devices to a number of hole-electron pairs recombined in the third color light-emitting devices; wherein
the first operating condition is an operating condition in which, for chromaticity coordinates of white light emitted by the display panel, an abscissa value is greater than or equal to 0.30 and less than or equal to 0.33 and an ordinate value is greater than or equal to 0.31 and less than or equal to 0.34, and a service life of the third color light-emitting devices is greater than or equal to 300 h.

19. The display panel according to claim 18, wherein a ratio of a sum of areas of the plurality of second light-emitting openings to a sum of areas of the plurality of first light-emitting openings satisfies a following formula 2:
$$\frac{2.833 {E}_{R} ( 1 - {RO}_{R} )}{{E}_{G} ( 1 - {RO}_{G} )} \leq \frac{SG}{SR} \leq \frac{3.043 {E}_{R} ( 1 - {RO}_{R} )}{{E}_{G} ( 1 - {RO}_{G} ) {k}_{lim}} ;$$
in the formula 2, SG represents a ratio of the sum of the areas of the plurality of second light-emitting openings to the area of the display region of the display panel; SR represents a ratio of the sum of the areas of the plurality of first light-emitting openings to the area of the display region of the display panel; E_{G} represents a current efficiency of the second color light-emitting devices in a case where a current density of the second color light-emitting devices is 10 mA/cm²; E_{R} represents a current efficiency of the first color light-emitting devices in a case where a current density of the first color light-emitting devices is 10 mA/cm²; RO_{G} represents a ratio of decrease in the current efficiency of the second color light-emitting devices in a case where the current density of the second color light-emitting devices is increased from 10 mA/cm² to 20 mA/cm²; RO_{R} represents a ratio of decrease in the current efficiency of the first color light-emitting devices in a case where the current density of the first color light-emitting devices is increased from 10 mA/cm² to 20 mA/cm²; kₗᵢₘ represents a maximum value of a ratio of an operating current of the second color light-emitting devices to an operating current of the first color light-emitting devices under a second operating condition; wherein
the second operating condition is an operating condition in which an operating luminance of the display panel is greater than or equal to 100 nit and less than or equal to 800 nit, and for the chromaticity coordinates of white light emitted by the display panel, the abscissa value is greater than or equal to 0.30 and less than or equal to 0.33, and the ordinate value is greater than or equal to 0.31 and less than or equal to 0.34.

20. A display apparatus, comprising:
a circuit board;
the display panel according to claim 1, wherein the display panel is located on a side of the circuit board, and the display panel is coupled to the circuit board.

21. A display apparatus, comprising:
a circuit board;
the display panel according to claim 18, wherein the display panel is located on a side of the circuit board, and the display panel is coupled to the circuit board.
